(19) United States
(12) Patent Application Publication
(10) Pub. No.: US 2025/0324590 A1
(43) Pub. Date: Oct. 16, 2025

(54) SEMICONDUCTOR DEVICE

(71) Applicant: SAMSUNG ELECTRONICS CO., LTD., Suwon-si (KR)

(72) Inventors: Kang Lib Kim, Suwon-si (KR); Kangoh Yun, Suwon-si (KR); Dongjin Lee, Suwon-si (KR); Jaeduk Lee, Suwon-si (KR)

(21) Appl. No.: 18/910,721

(22) Filed: Oct. 9, 2024

(30) Foreign Application Priority Data
Apr. 12, 2024 (KR) 10-2024-0049407

(51) Int. Cl. H10B 41/41; G11C 16/04; H10B 41/10; H10B 41/27; H10B 43/10; H10B 43/27; H10B 43/40

(52) U.S. Cl. CPC H10B 41/41; G11C 16/0483; H10B 41/10; H10B 41/27; H10B 43/10; H10B 43/27; H10B 43/40

(57) ABSTRACT

A semiconductor device includes a first substrate, a plurality of gate electrodes stacked on an upper surface of the first substrate in a vertical direction, the plurality of gate electrodes being apart from one another in the vertical direction, a channel structure passing through the plurality of gate electrodes, a second substrate disposed between the first substrate and a lowermost gate electrode of the plurality of gate electrodes, the second substrate including a first surface and a second surface opposite to the first surface, a buried pattern passing through the second substrate, and a vertical structure passing through the buried pattern, wherein the buried pattern includes a dielectric material.

### CROSS-REFERENCE TO RELATED APPLICATIONS

This application claims priority under 35 U.S.C. § 119 to Korean Patent Application No. 10-2024-0049407, filed on Apr. 12, 2024, in the Korean Intellectual Property Office, the disclosure of which is incorporated by reference herein in its entirety.

### BACKGROUND

Semiconductor devices for storing massive amounts of data are needed in electronic systems requiring data storage. Accordingly, it is required to increase the degree of integration of semiconductor devices so as to satisfy the low cost and good performance needed by consumers while increasing a data storage capacity. The degree of integration of one-dimensional or two-dimensional (2D) memory devices is determined by an area occupied by a unit memory cell and is thus largely affected by the level of a fine pattern formation technology. However, because expensive equipment is needed for forming fine patterns, the degree of integration of 2D semiconductor devices is increasing but is still limited. Therefore, three-dimensional (3D) semiconductor memory devices including three-dimensionally arranged memory cells have been proposed.

### SUMMARY

In general, in some aspects, the present disclosure is directed toward a semiconductor device with enhanced electrical characteristics, reliability, and degree of integration.

According to some implementations, the preset disclosure is directed to a semiconductor device that includes a first substrate, a plurality of gate electrodes stacked on an upper surface of the first substrate in a vertical direction, on the first substrate, the plurality of gate electrodes being apart from one another in the vertical direction, a channel structure passing through the plurality of gate electrodes, a second substrate disposed between the first substrate and a lowermost gate electrode of the plurality of gate electrodes, the second substrate including a first surface and a second surface opposite to the first surface, a buried pattern passing through the second substrate, and a vertical structure passing through the buried pattern, wherein the buried pattern includes a dielectric material.

According to some implementations, the present disclosure is directed to a semiconductor device that includes a first substrate, a first peripheral circuit transistor disposed on an upper surface of the first substrate, a plurality of gate electrodes stacked on the upper surface of the first substrate in a vertical direction, on the upper surface of the first substrate, the plurality of gate electrodes being apart from one another in the vertical direction, a channel structure passing through the plurality of gate electrodes, a second substrate disposed between the first substrate and a lowermost gate electrode of the plurality of gate electrodes, the second substrate including a first surface and a second surface opposite to the first surface, a second peripheral circuit transistor disposed on the first surface of the second substrate, a first through silicon via passing through the second substrate, the first through silicon via being electrically connected to the first peripheral circuit transistor and the channel structure, a buried pattern passing through the second substrate, and a vertical structure passing through the buried pattern, wherein a vertical level of a lower surface of the first through silicon via is substantially the same as a vertical level of a lower surface of the vertical structure.

According to some implementations, the present disclosure is directed to a semiconductor device that includes a first peripheral circuit structure, a cell structure on the first peripheral circuit structure, and a second peripheral circuit structure disposed between the first peripheral circuit structure and the cell structure, wherein the first peripheral circuit structure includes a first substrate including a cell region, a connection region next to the cell region, and a pad region surrounding at least a portion of each of the cell region and the connection region, a first peripheral circuit transistor disposed on an upper surface of the first substrate, and a first peripheral circuit wiring structure electrically connected to the first peripheral circuit transistor, the second peripheral circuit structure includes a second substrate including a first surface and a second surface opposite to the first surface, a second peripheral circuit transistor disposed on the first surface of the second substrate, a second peripheral circuit wiring structure electrically connected to the second peripheral circuit transistor, on the first surface of the second substrate, a buried pattern passing through the second substrate, and a vertical structure passing through the buried pattern, and accordingly, electrically connected to the first peripheral circuit wiring structure, and the cell structure includes a plurality of gate electrodes disposed apart from one another in a vertical direction, in the cell region, a channel structure passing through the plurality of gate electrodes and extending in the vertical direction in the cell region, a pad part extending from each of the plurality of gate electrodes and accordingly disposed in the connection region, a first contact plug passing through the pad part and extending in the vertical direction, the first contact plug being connected to the pad part, a stack insulation layer surrounding at least a portion of a side surface of each of the plurality of gate electrodes, and a second contact plug passing through the stack insulation layer in the pad region.

### BRIEF DESCRIPTION OF THE DRAWINGS

Implementations will be more clearly understood from the following detailed description, taken in conjunction with the accompanying drawings.

FIG. 1 is a block diagram of an example of a semiconductor device according to some implementations.

FIG. 2 is a circuit diagram illustrating an example of a memory block according to some implementations.

FIG. 3 is a perspective view illustrating an example of a representative configuration of a semiconductor device according to some implementations.

FIG. 4 is a plan layout view of the semiconductor device of FIG. 3 according to some implementations.

FIG. 5 is an enlarged layout view of an example of a region A of FIG. 4 according to some implementations.

FIGS. 6A and 6B are cross-sectional views taken along line B1-B1′ and line B2-B2′ of FIG. 5 according to some implementations.

FIG. 7 is a perspective view for describing an example of a vertical structure illustrated in FIG. 6A according to some implementations.

FIG. 8 is a cross-sectional view taken along line B1-B1′ of FIG. 5 according to some implementations.

FIG. 9 is a cross-sectional view taken along line B1-B1' of FIG. 5 according to some implementations.

FIG. 10 is a cross-sectional view taken along line B1-B1′ of FIG. 5 according to some implementations.

FIG. 11 is a cross-sectional view taken along line B1-B1′ of FIG. 5 according to some implementations.

FIG. 12 is a cross-sectional view taken along line B1-B1′ of FIG. 5 according to some implementations.

FIG. 13 is a cross-sectional view taken along line B1-B1′ of FIG. 5 according to some implementations.

FIG. 14 is a cross-sectional view taken along line B1-B1′ of FIG. 5 according to some implementations.

FIGS. 15A to 21B are diagrams illustrating an example of a method of manufacturing a semiconductor device according to some implementations, in which FIGS. 15A, 16A, 17A, 18A, 19A, 20A, and 21A are cross-sectional views taken along line B1-B1′ of FIG. 5, and FIGS. 15B, 16B, 17B, 18B, 19B, 20B, and 21B are cross-sectional views taken along line B2-B2′ of FIG. 5.

### DETAILED DESCRIPTION

Hereinafter, example implementations will be explained in detail with reference to the accompanying drawings.

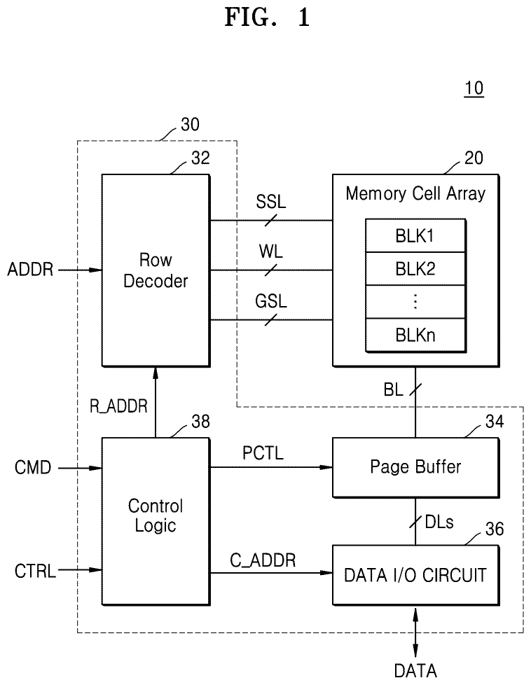

FIG. 1 is a block diagram of an example of a semiconductor device 10 according to some implementations.

Referring to FIG. 1, the semiconductor device 10 may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, and a control logic 38. In some implementations, the peripheral circuit 30 may further include an I/O interface, a column logic, a voltage generator, a pre-decoder, a temperature sensor, a command decoder, an address decoder, and an amplifier circuit.

The memory cell array 20 may be connected to the page buffer 34 through the bit line BL and may be connected to the row decoder 32 through the word line WL, the string selection line SSL, and the ground selection line GSL. In the memory cell array 20, each of the plurality of memory cells included in the plurality of memory cell blocks BLK1, BLK2, . . . , and BLKn may be a flash memory cell. The memory cell array 20 may include a three-dimensional (3D) memory cell array. The 3D memory cell array may include a plurality of NAND strings, and each of the plurality of NAND strings may include a plurality of memory cells respectively connected to a plurality of word lines WL which are vertically stacked on a substrate.

The peripheral circuit 30 may receive an address ADDR, a command CMD, and a control signal CTRL from the outside of the semiconductor device 10 and may transmit or receive an information signal DATA to or from a device outside the semiconductor device 10.

The row decoder 32 may select at least one memory cell block from among the plurality of memory cell blocks BLK1, BLK2, . . . , and BLKn in response to the address ADDR from the outside and may select a word line WL, a string selection line SSL, and a ground selection line GSL of the selected memory cell block. The row decoder 32 may transfer a voltage, which is for performing a memory operation, to the word line WL of the selected memory cell block.

The page buffer 34 may be connected to the memory cell array 20 through the bit line BL. In a program operation, the page buffer 34 may operate as a write driver to apply a voltage, based on the information signal DATA which is to be stored in the memory cell array 20, to the bit line BL, and in a read operation, the page buffer 34 may operate as a sense amplifier to sense data stored in the memory cell array 20. The page buffer 34 may operate based on a control signal PCTL provided from the control logic 38.

The data I/O circuit 36 may be connected to the page buffer 34 through data lines DLs. The data I/O circuit 36 may receive the information signal DATA from a memory controller (not shown) in a program operation and may provide a program information signal DATA to the page buffer 34, based on a column address C_ADDR supplied from the control logic 38. The data I/O circuit 36 may provide the memory controller with read information signal DATA stored in the page buffer 34, based on the column address C_ADDR.

The data I/O circuit 36 may transfer an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals used in the semiconductor device 10, in response to the control signal CTRL. For example, the control logic 38 may control a voltage level provided to the word line WL and the bit line BL when performing a memory operation such as a program operation or an erase operation.

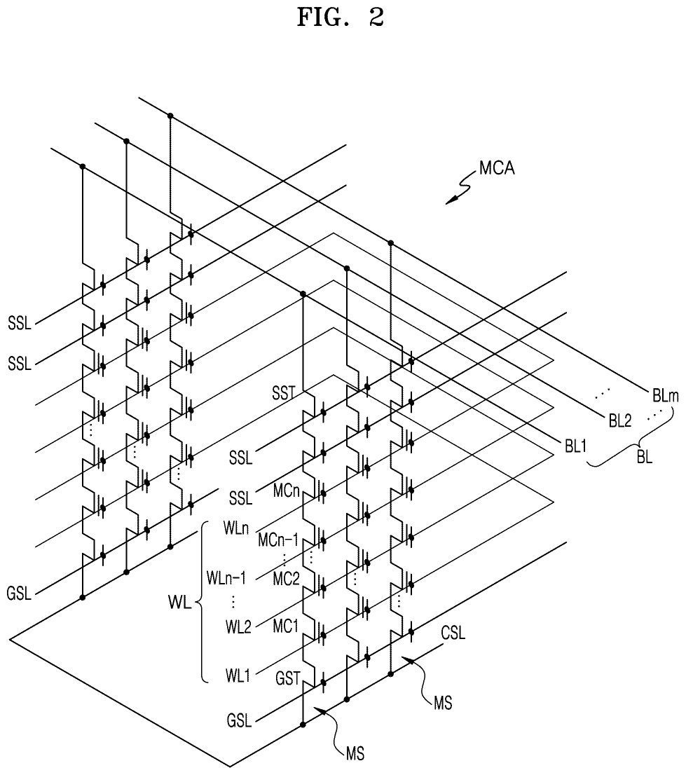

FIG. 2 is a circuit diagram illustrating an example of a memory block according to some implementations.

Referring to FIG. 2, a memory cell array MCA may include a plurality of memory cell strings MS. The memory cell array MCA may include a plurality of bit lines BL1, BL2, . . . , and BLm (BL), a plurality of word lines WL1, WL2, . . . , WLn−1, and WLn (WL), at least one string selection line SSL, at least one ground selection line GSL, and a common source line CSL. The plurality of memory cell strings MS may be formed between the plurality of bit lines BL1, BL2, . . . , and BLm (BL) and the common source line CSL. In FIG. 2, a case where each of the plurality of memory cell strings MS includes two string selection lines SSL is illustrated, but the present disclosure is not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn−1, and MCn. A drain region of the string selection transistor SST may be connected to the plurality of bit lines BL1, BL2, . . . , and BLm (BL), and a source region of the ground selection transistor GST may be connected to the common source line CSL. The common source line CSL may be a region which is connected to source regions of a plurality of ground selection transistors GST in common.

The string selection transistor SST may be connected to the string selection line SSL, and the ground selection transistor GST may be connected to the ground selection line GSL. The plurality of memory cell transistors MC1, MC2, . . . , MCn−1, and MCn may be respectively connected to the plurality of word lines WL1, WL2, . . . , WLn−1, and WLn (WL).

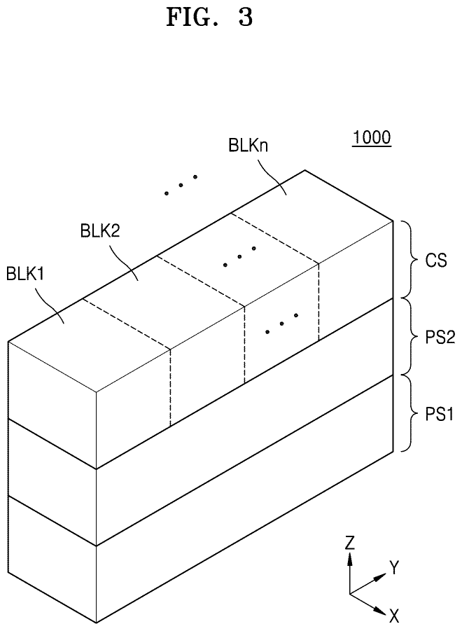

FIG. 3 is a perspective view illustrating an example of a representative configuration of a semiconductor device 1000 according to some implementations.

Referring to FIG. 3, the semiconductor device 1000 may include a first peripheral circuit structure PS1, a second peripheral circuit structure PS2, and a cell structure CS.

The cell structure CS may be disposed on the first peripheral circuit structure PS1. The second peripheral circuit structure PS2 may be disposed between the first peripheral circuit structure PS1 and the cell structure CS.

Each of the first peripheral circuit structure PS1 and the second peripheral circuit structure PS2 may include the peripheral circuit 30 described above with reference to FIG. 1. A portion of the peripheral circuit 30 described above with reference to FIG. 1 may be disposed in the first peripheral circuit structure PS1, and the other portion thereof may be disposed in the second peripheral circuit structure PS2.

For example, the first peripheral circuit structure PS1 may include a low voltage transistor, and the second peripheral circuit structure PS2 may include a high voltage transistor. The low voltage transistor may denote a transistor which operates with a relatively low voltage, and the high voltage transistor may denote a transistor which operates with a relatively high voltage. That is, the terms “low voltage” and “high voltage” may be relative. A relative level of a voltage for operating a transistor may vary based on a concentration of impurities doped into a source and a drain of the transistor.

However, a relative level of an operation voltage of a transistor included in the first peripheral circuit structure PS1 or an operation voltage of a transistor included in the second peripheral circuit structure PS2 may not be limited to the above descriptions. For example, the first peripheral circuit structure PS1 may include a high voltage transistor, and the second peripheral circuit structure PS2 may include a low voltage transistor. This may be modified based on a design of the semiconductor device 1000 to implement.

The cell structure CS may include the memory cell array 20 described above with reference to FIG. 1.

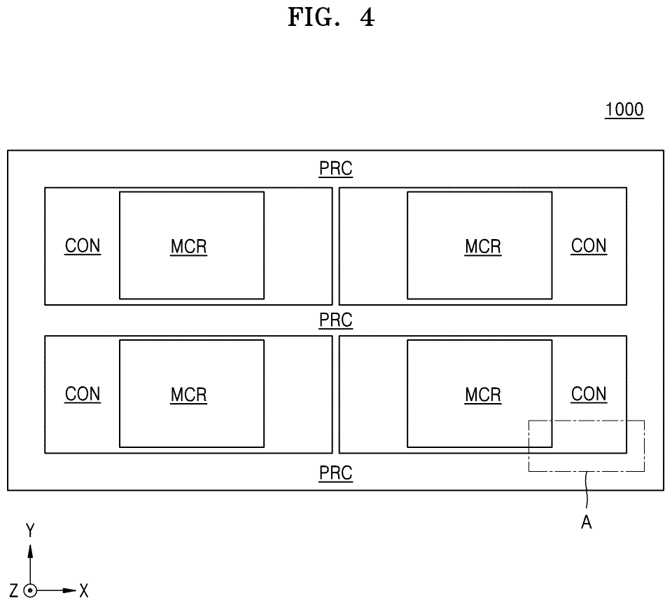

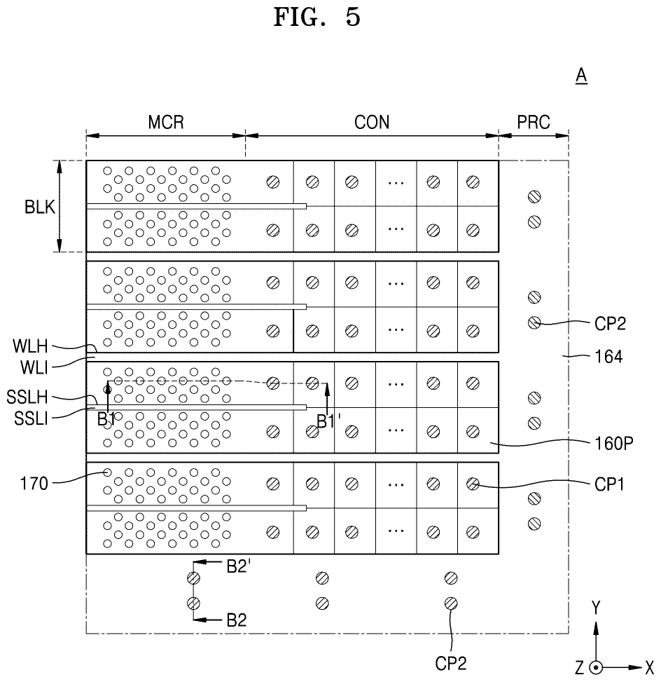

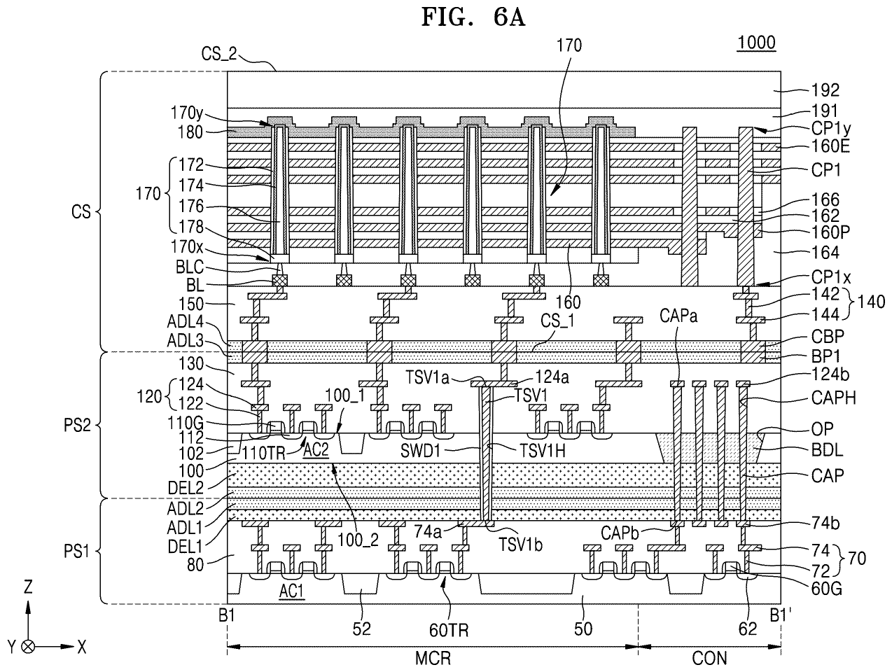

The cell structure CS may include a plurality of memory cell blocks BLK1, BLK2, . . . , and BLKn. Each of the plurality of memory cell blocks BLK1, BLK2, . . . , and BLKn may include a plurality of memory cells which are three-dimensionally arranged. For example, the plurality of memory cell blocks BLK1, BLK2, . . . , and BLKn may be arranged sequentially in a second horizontal direction Y. In FIG. 3, the definitions of a first horizontal direction X, the second horizontal direction Y, and a vertical direction Z may be the same as the definitions of a first horizontal direction X, a second horizontal direction Y, and a vertical direction Z in FIGS. 4 to 6B.

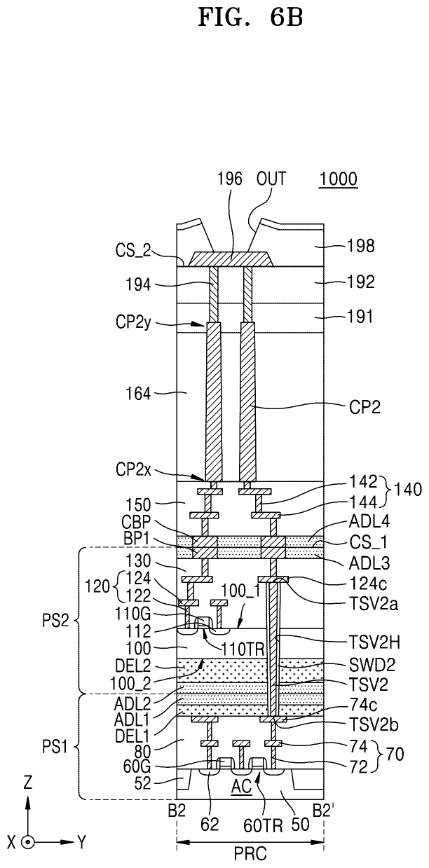

FIG. 4 is a plan layout view of the semiconductor device 1000 of FIG. 3 according to some implementations. FIG. 5 is an enlarged layout view of an example of a region A of FIG. 4. FIGS. 6A and 6B are cross-sectional views taken along line B1-B1′ and line B2-B2′ of FIG. 5, according to some implementations.

Referring to FIGS. 4 to 6B, a semiconductor device 1000 may include a first peripheral circuit structure PS1, a second peripheral circuit structure PS2, and a cell structure CS, which overlap each other in a vertical direction Z. The cell structure CS may include the memory cell array 20 described above with reference to FIG. 1, and the first peripheral circuit structure PS1 and the second peripheral circuit structure PS2 may each include the peripheral circuit 30 described above with reference to FIG. 1.

The first peripheral circuit structure PS1 may include a first substrate 50, a first peripheral circuit transistor 60TR, a first peripheral circuit wiring structure 70, a first peripheral circuit insulation layer 80, a first dielectric layer DEL1, and a first adhesive layer ADL1.

Herein, a first horizontal direction X may be one direction parallel to an upper surface of the first substrate 50, a second horizontal direction Y may be a direction which is parallel to the upper surface of the first substrate 50 and intersects with the first horizontal direction X, and the vertical direction Z may be defined as a direction perpendicular to the upper surface of the substrate 50.

The first substrate 50 may include a cell region MCR, a connection region CON, and a pad region PRC. As in FIG. 4, the connection region CON may be next to the cell region MCR in the first horizontal direction X, and the pad region PRC may surround at least a portion of each of the cell region MCR and the connection region CON.

A common source layer 180, a gate electrode 160, and a channel structure 170 which passes through the gate electrode 160 and is connected to the common source layer 180 may be disposed in the cell region MCR.

A pad part 160P of the gate electrode 160 and a first contact plug CP1 which passes through the pad part 160P and is electrically connected to the pad part 160P may be disposed in the connection region CON.

A plurality of backside pads 196 and a second contact plug CP2 which electrically connects the backside pad 196 to the first peripheral circuit wiring structure 70 or the backside pad 196 to the second peripheral wiring structure 120 may be disposed in the pad region PRC.

The first substrate 50 may include, for example, Group IV semiconductors, Group III-V compound semiconductors, or Group II-VI oxide semiconductors. For example, the Group IV semiconductors may include silicon (Si), germanium (Ge), or silicon-germanium (SiGe). The first substrate 50 may be provided as a bulk wafer or an epitaxial layer. In some implementations, the first substrate 50 may include a silicon-on-insulator (SOI) substrate or a germanium-on-insulator (GeOI) substrate.

A first active region AC1 may be defined by a first device isolation layer 52 in the first substrate 50. A plurality of first peripheral circuit transistors 60TR may be formed on the first active region AC1 of the first substrate 50. Each of the plurality of first peripheral circuit transistors 60TR may include a first peripheral circuit gate 60G and a first source/drain region 62 disposed at both sides of the first peripheral circuit gate 60G. The first source/drain region 62 may be disposed at a portion of the first substrate 50. The first source/drain region 62 may be a region, doped with impurities, of the first substrate 50. The impurities may be an n type or a p type.

The first peripheral circuit wiring structure 70 may be disposed on the first substrate 50. The first peripheral circuit wiring structure 70 may include a plurality of first peripheral circuit contacts 72 and a plurality of first peripheral circuit wirings 74. The first peripheral circuit contact 72 may connect the first source/drain region 62 to the first peripheral circuit wiring 74. Alternatively, the first peripheral circuit contact 72 may connect, with each other, two first peripheral circuit wirings 74 disposed at different vertical levels.

A length of the first peripheral circuit contact 72 in a horizontal direction (for example, the first horizontal direction X or the second horizontal direction Y) may be greater than that of the first peripheral circuit contact 72 in the vertical direction Z.

A length of the first peripheral circuit wiring 74 in the vertical direction Z may be greater than that of the first peripheral circuit wiring 74 in the horizontal direction (for example, the first horizontal direction X or the second horizontal direction Y).

In FIGS. 6A and 6B, the first peripheral circuit wiring 74 is shown to be configured comprising two layers, but the first peripheral circuit wiring 74 may have a single-layer structure, or may have a multi-layer (three or more-layer) structure.

The first peripheral circuit contact 72 and the first peripheral circuit wiring 74 may include a conductive material. For example, the first peripheral circuit contact 72 and the first peripheral circuit wiring 74 may include a metal material, such as tungsten, aluminum, copper, gold, silver, cobalt, or molybdenum, or is not limited thereto.

The first peripheral circuit insulation layer 80 may be disposed on the first substrate 50. The first peripheral circuit insulation layer 80 may extend in the first horizontal direction X or the second horizontal direction Y up to the pad region PCR via the connection region CON from the cell region MCR. The first peripheral circuit insulation layer 80 may cover the plurality of first peripheral circuit transistor 60TR. The first peripheral circuit insulation layer 80 may cover at least a portion of the first peripheral circuit wiring structure 70.

An upper surface of the first peripheral circuit insulation layer 80 may be coplanar with an upper surface of an uppermost first peripheral circuit wiring 74 of the plurality of first peripheral circuit wirings 74. Alternatively, a vertical level of the upper surface of the first peripheral circuit insulation layer 80 may be higher than a vertical level of the upper surface of the uppermost first peripheral circuit wiring 74 of the plurality of first peripheral circuit wirings 74.

The first peripheral circuit insulation layer 80 may include an insulating material. For example, the first peripheral circuit insulation layer 80 may include a low-k dielectric material. For example, the first peripheral circuit insulation layer 80 may include SiO₂, SiN, SiOCN, SiOC, SiON, or a combination thereof.

The first dielectric layer DEL1 may be disposed on the first peripheral circuit insulation layer 80. The first dielectric layer DEL1 may extend in the first horizontal direction X or the second horizontal direction Y up to the pad region PCR via the connection region CON from the cell region MCR.

The first dielectric layer DEL1 may cover the upper surface of the uppermost first peripheral circuit wiring 74 of the plurality of first peripheral circuit wirings 74, but is not limited thereto. The first dielectric layer DEL1 may be apart from the uppermost first peripheral circuit wiring 74 of the plurality of first peripheral circuit wirings 74 in the vertical direction Z.

The first dielectric layer DEL1 may include a dielectric material. For example, the first dielectric layer DEL1 may include a high-k dielectric material. The first dielectric layer DEL1 may include a high-k dielectric material having a dielectric constant which is greater than that of SiO₂. For example, the first dielectric layer DEL1 may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate, but is not limited thereto.

In some implementations, the first dielectric layer DEL1 may include a low-k dielectric material. For example, the first dielectric layer DEL1 may include SiO₂, SiN, SiOCN, SiOC, SiON, or a combination thereof, but is not limited thereto.

The first adhesive layer ADL1 may be disposed on an upper surface of the first dielectric layer DEL1. The first dielectric layer DEL1 may be disposed between the first adhesive layer ADL1 and the first peripheral circuit insulation layer 80. The first adhesive layer ADL1 may extend in the first horizontal direction X or the second horizontal direction Y up to the pad region PCR via the connection region CON from the cell region MCR.

The first adhesive layer ADL1 may contact a second adhesive layer ADL2. The first adhesive layer ADL1 may perform a function of fixing the first peripheral circuit structure PS1 and the second peripheral circuit structure PS2. However, a function of the first adhesive layer ADL1 is not limited thereto.

The first adhesive layer ADL1 may include an insulating material. For example, the first adhesive layer ADL1 may include silicon nitride. In detail, the first adhesive layer ADL1 may include SiN, SiCN, or the like, but is not limited thereto.

The second peripheral circuit structure PS2 may include a second substrate 100, a second peripheral circuit transistor 110TR, a buried pattern BDL, a second peripheral circuit wiring structure 120, a second peripheral circuit insulation layer 130, a second dielectric layer DEL2, the second adhesive layer ADL2, a third adhesive layer ADL3, a first bonding pad BP1, a first through silicon via TSV1, a second through silicon via TSV2, and a vertical structure CAP.

The second substrate 100 may be disposed on the first peripheral circuit structure PS1. The second substrate 100 may extend in the first horizontal direction X or the second horizontal direction Y up to the pad region PCR via the connection region CON from the cell region MCR.

The second substrate 100 may include, for example, Group IV semiconductors, Group III-V compound semiconductors, or Group II-VI oxide semiconductors. For example, the Group IV semiconductors may include silicon (Si), germanium (Ge), or SiGe. The second substrate 100 may be provided as a bulk wafer or an epitaxial layer. In some implementations, the second substrate 100 may include an SOI substrate or a GeOI substrate.

The second substrate 100 may include a first surface 100_1 facing the cell structure CS and a second surface 100_2 facing the first peripheral circuit structure PS1. The second surface 100_2 may be a surface facing the first surface 100_1.

The buried pattern BDL filling an opening portion OP passing through the second substrate 100 may be provided. In FIG. 6A, the opening portion OP and the buried pattern BDL are shown disposed in the connection region CON, but the opening portion OP and the buried pattern BDL may be disposed in the cell region MCR or the pad region PRC. In a plain viewpoint, a position of the buried pattern BDL may not be limited thereto.

A sidewall of the opening portion OP may be inclined with respect to the first surface 100_1 of the second substrate 100. Therefore, a width of the buried pattern BDL in the horizontal direction may decrease progressively toward the first surface 100_1 of the second substrate 100 from the second surface 100_2 of the second substrate 100, but the inventive concept is not limited thereto.

In a plain viewpoint, a shape of the buried pattern BDL may not be limited to a specific shape also. For example, a one-dimensional shape of the buried pattern BDL may be circular, oval, or polygonal. For example, in a plain viewpoint, the buried pattern BDL may have a shape which extends long in the first horizontal direction X or the second horizontal direction Y. In some implementations, the buried pattern BDL may be provided in plurality in one or more regions of the cell region MCR, the connection region CON, and the pad region PRC. This may be modified based on a design of the semiconductor device 1000 to implement.

An upper surface of the buried pattern BDL may be coplanar with the first surface 100_1 of the second substrate 100. A lower surface of the buried pattern BDL may be coplanar with the second surface 100_2 of the second substrate 100.

The buried pattern BDL may include a dielectric material. For example, the buried pattern BDL may include a low-k dielectric material. For example, the buried pattern BDL may include SiO₂, SiN, SiOCN, SiOC, SiON, or a combination thereof.

In some implementations, the buried pattern BDL may include a high-k dielectric material. The buried pattern BDL may include, for example, a high-k dielectric material having a dielectric constant which is greater than that of SiO₂. For example, the buried pattern BDL may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate, but is not limited thereto.

A second active region AC2 may be defined by a second device isolation layer 102 in the second substrate 100. A plurality of second peripheral circuit transistors 110TR may be formed on the second active region AC2 of the second substrate 100. The plurality of second peripheral circuit transistors 110TR may be disposed on the first surface 100_1 of the second substrate 100.

Each of the plurality of second peripheral circuit transistors 100TR may include a second peripheral circuit gate 110G and a second source/drain region 112 disposed at both sides of the second peripheral circuit gate 110G. The second source/drain region 112 may be disposed at a portion of the second substrate 100. The second source/drain region 112 may be disposed at a portion of the first surface 100_1 of the second substrate 100. The second source/drain region 112 may be a region, doped with impurities, of the second substrate 110. The impurities may be an n type or a p type.

The second peripheral circuit wiring structure 120 may include a plurality of second peripheral circuit contacts 122 and a plurality of second peripheral circuit wirings 124. The second peripheral circuit contact 122 may connect the second source/drain region 112 to the second peripheral circuit wiring 124. Alternatively, the second peripheral circuit contact 122 may connect, with each other, two second peripheral circuit wirings 124 disposed at different vertical levels.

A length of the second peripheral circuit contact 122 in a horizontal direction (for example, the first horizontal direction X or the second horizontal direction Y) may be greater than that of the second peripheral circuit contact 122 in the vertical direction Z.

A length of the second peripheral circuit wiring 124 in the vertical direction Z may be greater than that of the second peripheral circuit wiring 124 in the horizontal direction (for example, the first horizontal direction X or the second horizontal direction Y).

In FIGS. 6A and 6B, the second peripheral circuit wiring 124 is shown comprising two layers, but the second peripheral circuit wiring 124 may have a single-layer structure, or may have a multi-layer (three or more-layer) structure.

The second peripheral circuit contact 122 and the second peripheral circuit wiring 124 may include a conductive material. For example, the second peripheral circuit contact 122 and the second peripheral circuit wiring 124 may include a metal material such as tungsten, aluminum, copper, gold, silver, cobalt, or molybdenum, or is not limited thereto.

The second peripheral circuit insulation layer 130 may be disposed on the first surface 100_1 of the second substrate 100. The second peripheral circuit insulation layer 130 may extend in the first horizontal direction X and the second horizontal direction Y up to the pad region PCR via the connection region CON from the cell region MCR.

The second peripheral circuit insulation layer 130 may cover the plurality of second peripheral circuit transistor 110TR. The second peripheral circuit insulation layer 130 may cover at least a portion of the second peripheral circuit wiring structure 120.

A vertical level of the upper surface of the second peripheral circuit insulation layer 130 may be higher than a vertical level of the upper surface of the uppermost second peripheral circuit wiring 124 of the plurality of second peripheral circuit wirings 124. For example, the upper surface of the second peripheral circuit insulation layer 130 may be coplanar with an upper surface of an uppermost second peripheral circuit contact 122 of the plurality of second peripheral circuit contacts 122. In some implementations, the upper surface of the second peripheral circuit insulation layer 130 may be coplanar with the upper surface of the uppermost second peripheral circuit wiring 124 of the plurality of second peripheral circuit wirings 124.

The second peripheral circuit insulation layer 130 may include an insulating material. For example, the second peripheral circuit insulation layer 120 may include a low-k dielectric material. For example, the second peripheral circuit insulation layer 130 may include SiO₂, SiN, SiOCN, SiOC, SiON, or a combination thereof.

The second dielectric layer DEL2 may be disposed on the second surface 100_2 of the second substrate 100. The second dielectric layer DEL2 may extend in the first horizontal direction X and the second horizontal direction Y up to the pad region PCR via the connection region CON from the cell region MCR.

The second dielectric layer DEL2 may cover the surface 100_2 of the second substrate 100, but is not limited thereto. The second dielectric layer DEL2 may cover a lower surface of the buried pattern BDL, but is not limited thereto.

The second dielectric layer DEL2 may include a dielectric material. For example, the second dielectric layer DEL2 may include a high-k dielectric material. The second dielectric layer DEL2 may include a high-k dielectric material having a dielectric constant which is greater than that of SiO₂. For example, the second dielectric layer DEL2 may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate, but is not limited thereto.

In some implementations, the second dielectric layer DEL2 may include a low-k dielectric material. For example, the second dielectric layer DEL2 may include SiO₂, SiN, SiOCN, SiOC, SiON, or a combination thereof, but is not limited thereto.

The second adhesive layer ADL2 may be disposed on a lower surface of the second dielectric layer DEL2. The second dielectric layer DEL2 may be disposed between the second substrate 100 and the second adhesive layer ADL2. The second adhesive layer ADL2 may extend in the first horizontal direction X and the second horizontal direction Y up to the pad region PCR via the connection region CON from the cell region MCR.

The second adhesive layer ADL2 may contact a first adhesive layer ADL1. The second adhesive layer ADL2 may perform a function of fixing the first peripheral circuit structure PS1 and the second peripheral circuit structure PS2. However, a function of the second adhesive layer ADL2 is not limited thereto.

The second adhesive layer ADL2 may include an insulating material. For example, the second adhesive layer ADL2 may include silicon nitride. For example, the second adhesive layer ADL2 may include SiN, SiCN, or the like, but is not limited thereto.

The third adhesive layer ADL3 may be disposed on an upper surface of the second peripheral circuit insulation layer 130. The third adhesive layer ADL3 may extend in the first horizontal direction X and the second horizontal direction Y up to the pad region PCR via the connection region CON from the cell region MCR.

The third adhesive layer ADL3 may cover the upper surface of the uppermost second peripheral circuit wiring 124 of the plurality of second peripheral circuit wirings 124 or the upper surface of the uppermost second peripheral circuit wiring 122 of the plurality of second peripheral circuit wirings 122, but is not limited thereto.

The third adhesive layer ADL3 may include an insulating material. For example, the third adhesive layer ADL3 may include silicon nitride. For example, the third adhesive layer ADL3 may include SiN, SiCN, or the like, but is not limited thereto.

A plurality of first bonding pads BP1 may be disposed on an upper surface of the second peripheral circuit insulation layer 130. The third adhesive layer ADL3 may surround at least a portion of a side surface of each of the plurality of first bonding pads BP1.

The first bonding pad BP1 may include a conductive material. For example, the first bonding pad BP1 may include tungsten, aluminum, copper, gold, silver, or molybdenum, or is not limited thereto.

A first through silicon via TSV1 may be provided in a first through silicon via hole TSV1H passing through the second substrate 100, the second dielectric layer DEL2, the second adhesive layer ADL2, and the first adhesive layer ADL1.

The first through silicon via TSV1 may further extend into the second peripheral circuit insulation layer 130 in the vertical direction Z. In some implementations, the first through silicon via TSV1 may further extend into the first peripheral circuit insulation layer 80 in a direction opposite to the vertical direction Z.

In FIGS. 6A and 6B, the first through silicon via TSV1 is shown disposed in the cell region MCR, but the first through silicon via TSV1 may be disposed in the connection region CON or the pad region PRC. The first through silicon via TSV1 may be provided in plurality.

The first through silicon via TSV1 may be electrically connected to the first peripheral circuit wiring structure 70. For example, the first through silicon via TSV1 may directly contact one first peripheral circuit wiring 74a of the plurality of first peripheral circuit wirings 74. The first through silicon via TSV1 may be electrically connected to the first peripheral circuit transistor 60TR through the first peripheral circuit wiring structure 70.

The first through silicon via TSV1 may be electrically connected to the second peripheral circuit wiring structure 120. For example, the first through silicon via TSV1 may directly contact one second peripheral circuit wiring 124a of the plurality of second peripheral circuit wirings 124. The first through silicon via TSV1 may be electrically connected to the first bonding pad BP1 through the second peripheral circuit wiring structure 120.

In some implementations, the first through silicon via TSV1 may be electrically connected to the second peripheral circuit transistor 110TR through the second peripheral circuit wiring structure 120. In this case, the first peripheral circuit transistor 60TR and the second peripheral circuit transistor 110TR may be electrically connected to each other through the first through silicon via TSV1.

The first through silicon via TSV1 may include a conductive material. For example, the first through silicon via TSV1 may include tungsten, aluminum, copper, gold, silver, cobalt, or molybdenum, or is not limited thereto.

A first sidewall insulation pattern SWD1 surrounding at least a portion of a side surface of the first through silicon via TSV1 may be provided. The first sidewall insulation pattern SWD1 may cover a side surface of the first through silicon via hole TSV1H.

The first sidewall insulation pattern SWD1 may be disposed between the first through silicon via TSV1 and the second peripheral circuit insulation layer 130, between the first through silicon via TSV1 and the second substrate 100, between the first through silicon via TSV1 and the second dielectric layer DEL2, between the first through silicon via TSV1 and the second adhesive layer ADL2, and between the first through silicon via TSV1 and the first adhesive layer ADL1.

The first sidewall insulation pattern SWD1 may include a dielectric material. For example, the first sidewall insulation pattern SWD1 may include SiO₂, SiN, SiOCN, SiOC, SiON, or a combination thereof, but is not limited thereto.

A vertical structure CAP may be provided in a vertical structure hole CAPH passing through the buried layer BDL, the second dielectric layer DEL2, the second adhesive layer ADL2, and the first adhesive layer ADL1.

The vertical structure CAP may further extend into the second peripheral circuit insulation layer 130 in the vertical direction Z. In some implementations, the vertical structure CAP may further extend into the first peripheral circuit insulation layer 80 in a direction opposite to the vertical direction Z.

The vertical structure CAP may be apart from the second substrate 100 in the horizontal direction with the buried pattern BDL therebetween.

In a plain viewpoint, the vertical structure CAP may be disposed in the buried pattern BDL. In FIGS. 6A and 6B, the vertical structure CAP is shown disposed in the connection region CON, but the vertical structure CAP may be disposed in at least one region of the cell region MCR, the connection region CON, and the pad region PRC. The buried pattern BDL may surround at least a portion of a side surface of the vertical structure CAP.

The vertical structure CAP may be electrically connected to the first peripheral circuit wiring structure 70. For example, the vertical structure CAP may directly contact one first peripheral circuit wiring 74a of the plurality of first peripheral circuit wirings 74. The vertical structure CAP may be electrically connected to one first peripheral circuit wiring 74b of the plurality of first peripheral circuit wirings 74. In this case, the first peripheral circuit wiring 74b electrically connected to the vertical structure CAP may be configured to be electrically connected to the first peripheral circuit transistor 60TR, or may be configured to be electrically disconnected therefrom.

The vertical structure CAP may be electrically connected to the second peripheral circuit wiring structure 120. For example, the vertical structure CAP may directly contact one second peripheral circuit wiring 124b of the plurality of second peripheral circuit wirings 124. The vertical structure CAP may be electrically connected to the one second peripheral circuit wiring 124b of the plurality of second peripheral circuit wirings 124. In this case, the second peripheral circuit wiring 124b electrically connected to the vertical structure CAP may be configured to be electrically connected to the second peripheral circuit transistor 110TR, or may be configured to be electrically disconnected therefrom.

The vertical structure CAP may be electrically connected to one of the first peripheral circuit transistor 60TR and the second peripheral circuit transistor 110TR. In a case where the vertical structure CAP is electrically connected to the first peripheral circuit transistor 60TR, the vertical structure CAP may be configured to be electrically disconnected from the second peripheral circuit transistor 110TR. In this case, the one second peripheral circuit wiring 124b electrically connected to the vertical structure CAP may be configured to be electrically disconnected from the second peripheral circuit transistor 110TR.

On the other hand, in a case where the vertical structure CAP is electrically connected to the second peripheral circuit transistor 110TR, the vertical structure CAP may be configured to be electrically disconnected from the first peripheral circuit transistor 60TR. In this case, the one first peripheral circuit wiring 74b electrically connected to the vertical structure CAP may be configured to be electrically disconnected from the first peripheral circuit transistor 60TR.

In some implementations, the vertical structure CAP may not be electrically connected to any one of the first peripheral circuit transistor 60TR and the second peripheral circuit transistor 110TR. In this case, the one first peripheral circuit wiring 74b electrically connected to the vertical structure CAP may be configured to be electrically disconnected from the first peripheral circuit transistor 60TR. Likewise, the one second peripheral circuit wiring 124b electrically connected to the vertical structure CAP may be configured to be electrically disconnected from the second peripheral circuit transistor 110TR.

The vertical structure CAP may be provided in plurality. The plurality of vertical structures CAP may be apart from one another in the horizontal direction (for example, the first horizontal direction X and/or the second horizontal direction Y). For example, two vertical structures CAP may be apart from each other in the first horizontal direction X with the buried pattern BDL therebetween. Likewise, the two vertical structures CAP may be apart from each other in the first horizontal direction X with the second peripheral circuit insulation layer 130, the second dielectric layer DEL2, the second adhesive layer ADL2, the first adhesive layer ADL1, and the first dielectric layer DEL1 therebetween.

In this case, the two vertical structures CAP and dielectric elements (the buried pattern BDL, the second peripheral circuit insulation layer 130, the second dielectric layer DEL2, the second adhesive layer ADL2, the first adhesive layer ADL1, and the first dielectric layer DEL1) therebetween may configure a capacitor. The two vertical structures CAP may function as an electrode plate of the capacitor, and the dielectric elements described above may function as a dielectric layer.

Hereinabove, it has been described that two vertical structures CAP configure a capacitor, but the present disclosure is not limited thereto and three or more vertical structures CAP may configure a capacitor. This may be modified based on a design of the semiconductor device 1000 to implement.

The vertical structure CAP may include a conductive material. For example, the vertical structure CAP may include a metal material such as tungsten, aluminum, copper, gold, silver, cobalt, or molybdenum, or is not limited thereto.

The first peripheral circuit structure PS1 may include passive elements such as a capacitor, a resistor, and an inductor, as well as an active element such as the first peripheral circuit transistor 60TR. Likewise, the second peripheral circuit structure PS2 may include passive elements such as a capacitor, a resistor, and an inductor, as well as an active element such as the second peripheral circuit transistor 110TR.

In this case, in a case where a passive element is formed on the upper surface of the first substrate 50 of the first peripheral circuit structure PS1 or the first surface 100_1 of the second substrate 100 of the second peripheral circuit structure PS2, a magnitude of the passive element may be limited. For example, in a case where a capacitor is formed on a surface of the first substrate 50 and/or a surface of the second substrate 100, there may be a limitation in enlarging an area of an electrode plate of the capacitor. In this case, there may be a limitation in increasing an electrical capacity of a capacitor, and due to this, an electrical characteristic of the semiconductor device 1000 may be degraded.

Similar to a capacitor, in a case where a resistor and an inductor are formed on the surfaces of the first substrate 50 and the second substrate 100, there may be a limitation in increasing a length of each of the resistor and the inductor. Considering with being affect by characteristics of a resistor and an inductor and lengths of the resistor and the inductor, it may be difficult to control an electrical characteristic of the semiconductor device 1000.

In some implementations, the semiconductor device 1000 may include a buried pattern BDL passing through the second substrate 100 and a vertical structure CAP passing through the buried pattern BDL. The buried pattern BDL may include a dielectric material, and the vertical structure CAP may include a conductive material. The vertical structure CAP may be electrically connected to at least one of the first peripheral circuit transistor 60TR and the second peripheral circuit transistor 110TR.

Accordingly, two or more vertical structures CAP and buried patterns BDL may configure a capacitor, and the vertical structure CAP may configure an electrode plate of the capacitor. In this case, the vertical structure CAP may extend in the vertical direction Z, and an area of an electrode plate of the capacitor may enlarge. In this case, a capacitance of the capacitor may increase, and an electrical characteristic of the semiconductor device 1000 may be enhanced.

Also, the vertical structure CAP may pass through the buried pattern BDL, and a length of the vertical structure CAP in the vertical direction Z may increase. Therefore, a horizontal area of the vertical structure CAP may relatively decrease, and the degree of integration of the semiconductor device 1000 may be enhanced.

A second through silicon via TSV2 may be provided in a second through silicon via hole TSV2H passing through the second substrate 100, the second dielectric layer DEL2, the second adhesive layer ADL2, and the first adhesive layer ADL1. The second through silicon via TSV2 may further extend into the second peripheral circuit insulation layer 130 in the vertical direction Z. In some implementations, the second through silicon via TSV2 may further extend into the first peripheral circuit insulation layer 80 in a direction opposite to the vertical direction Z.

The second through silicon via TSV2 may be disposed in the pad region PRC. The first through silicon via TSV1 may be provided in plurality.

The second through silicon via TSV2 may be electrically connected to the first peripheral circuit wiring structure 70. For example, the second through silicon via TSV2 may directly contact one first peripheral circuit wiring 74c of the plurality of first peripheral circuit wirings 74. The second through silicon via TSV2 may be electrically connected to the first peripheral circuit transistor 60TR through the first peripheral circuit wiring structure 70.

The second through silicon via TSV2 may be electrically connected to the second peripheral circuit wiring structure 120. For example, the second through silicon via TSV2 may directly contact one second peripheral circuit wiring 124c of the plurality of second peripheral circuit wirings 124. The second through silicon via TSV2 may be electrically connected to the first bonding pad BP1 through the second peripheral circuit wiring structure 120.

The second through silicon via TSV2 may include a conductive material. The second through silicon via TSV2 may include tungsten, aluminum, copper, gold, silver, cobalt, or molybdenum, or is not limited thereto.

A second sidewall insulation pattern SWD2 surrounding at least a portion of a side surface of the second through silicon via TSV2 may be provided. The second sidewall insulation pattern SWD2 may cover a side surface of the second through silicon via hole TSV2H.

The second sidewall insulation pattern SWD2 may be disposed between the second through silicon via TSV2 and the second peripheral circuit insulation layer 130, between the second through silicon via TSV2 and the second substrate 100, between the second through silicon via TSV2 and the second dielectric layer DEL2, between the second through silicon via TSV2 and the second adhesive layer ADL2, and between the second through silicon via TSV2 and the first adhesive layer ADL1.

The second sidewall insulation pattern SWD2 may include a dielectric material. For example, the second sidewall insulation pattern SWD2 may include SiO2, SiN, SiOCN, SiOC, SiON, or a combination thereof, but is not limited thereto.

A vertical level of an upper surface CAPa of the vertical structure CAP may be substantially the same as a vertical level of an upper surface TSV1a of the first through silicon via TSV1 and a vertical level of an upper surface TSV2a of the second through silicon via TSV2.

Herein, the meaning “substantially the same” may be a concept which includes mathematical same and an error range of a process.

A vertical level of a lower surface CAPb of the vertical structure CAP may be substantially the same as a vertical level of a lower surface TSV1b of the first through silicon via TSV1 and a vertical level of a lower surface TSV2b of the second through silicon via TSV2.

The cell structure CS may include a cell bonding pad CBP, a fourth adhesive layer ADL4, a cell wiring structure 140, a cell wiring insulation layer 150, a gate electrode 160, a mold insulation layer 162, a stack insulation layer 164, a channel structure 170, a first contact plug CP1, a second contact plug CP2, a common source layer 180, a first upper insulation layer 191, a second upper insulation layer 192, a backside pad 196, and a passivation layer 198.

The cell structure CS may include a third surface CS_1 connected to the second peripheral circuit structure PS2 and a fourth surface CS_2 opposite to the third surface CS_1.

The fourth adhesive layer ADL4 may be disposed on the third adhesive layer ADL3. The fourth adhesive layer ADL4 may extend in the first horizontal direction X and the second horizontal direction Y up to the pad region PCR via the connection region CON from the cell region MCR. The fourth adhesive layer ADL4 may contact at least a portion of the third adhesive layer ADL3.

The fourth adhesive layer ADLA may include an insulating material. For example, the fourth adhesive layer ADL4 may include silicon nitride. For example, the fourth adhesive layer ADL4 may include SiN, SiCN, or the like, but is not limited thereto.

A plurality of cell bonding pads CBP may be disposed on an upper surface of the third adhesive layer ADL3. The fourth adhesive layer ADL4 may surround at least a portion of a side surface of each of the plurality of cell bonding pads CBP.

The cell bonding pad CBP of the cell structure CS may be connected to a first bonding pad BP1 of the second peripheral circuit structure PS2. The cell bonding pad CBP may contact the first bonding pad BP1, and the cell bonding pad CBP and the first bonding pad BP1 may be configured as one body. However, in some implementations, the cell bonding pad CBP and the first bonding pad BP1 may be configured to be differentiated from each other.

The cell bonding pad CBP may contact the first bonding pad BP1, the fourth adhesive layer ADL4 may contact the third adhesive layer ADL3, and the cell structure CS may be hybrid-bonded to the second peripheral circuit structure PS2. However, in some implementations, the cell bonding pad CBP and the first bonding pad BP1 may be omitted. In this case, the cell structure CS may be bonded to the second peripheral circuit structure PS2 by the third adhesive layer ADL3 and the fourth adhesive layer ADL4.

The cell wiring structure 140 and the cell wiring insulation layer 150 may be disposed on the fourth adhesive layer ADL4. The cell wiring structure 140 may be configured to be electrically connected to the cell bonding pad CBP. The cell wiring structure 140 may include a plurality of cell contacts 142 and a plurality of cell wirings 144.

The cell contact 142 may connect the cell bonding pad CBP to the cell wiring 144. Alternatively, the cell contact 142 may connect, with each other, two cell wirings 144 disposed at different vertical levels.

A length of the cell contact 142 in the horizontal direction (for example, the first horizontal direction X or the second horizontal direction Y) may be greater than that of the cell contact 142 in the vertical direction Z.

A length of the cell wiring 144 in the vertical direction Z may be greater than that of the cell wiring 144 in the horizontal direction (for example, the first horizontal direction X or the second horizontal direction Y).

In FIGS. 6A and 6B, the cell wiring 144 is shown comprising two layers, but the cell wiring 144 may have a single-layer structure, or may have a multi-layer (three or more-layer) structure.

The cell contact 142 and the cell wiring 144 may include a conductive material. For example, the cell contact 142 and the cell wiring 144 may include a metal material, such as tungsten, aluminum, copper, gold, silver, cobalt, or molybdenum, or is not limited thereto.

The cell wiring insulation layer 150 may be disposed on the fourth adhesive layer ADL4. The cell wiring insulation layer 150 may extend in the first horizontal direction X and the second horizontal direction Y up to the pad region PCR via the connection region CON from the cell region MCR. The cell wiring insulation layer 150 may cover at least a portion of the cell wiring structure 140.

A vertical level of an upper surface of the cell wiring insulation layer 150 may be higher than a vertical level of an upper surface of an uppermost cell wiring 144 of the plurality of cell wirings 144. Alternatively, the upper surface of the cell wiring insulation layer 150 may be coplanar with the upper surface of the uppermost cell wiring 144 of the plurality of cell wirings 144.

The cell wiring insulation layer 150 may include an insulating material. For example, the cell wiring insulation layer 150 may include a low-k dielectric material. For example, the cell wiring insulation layer 150 may include SiO₂, SiN, SiOCN, SiOC, SiON, or a combination thereof.

The gate electrode 160 and the mold insulation layer 162 may be disposed on the cell wiring insulation layer 150. Each of the gate electrode 160 and the mold insulation layer 162 may be provided in plurality. The gate electrode 160 and the mold insulation layer 162 may be disposed in the cell region MCR and the connection region CON.

A plurality of gate electrodes 160 may be disposed spaced apart from one another in the vertical direction Z. A plurality of mold insulation layers 162 may be disposed spaced apart from one another in the vertical direction Z. The plurality of gate electrodes 160 and the plurality of mold insulation layers 162 may be alternately stacked one-by-one.

The gate electrode 160 may extend from the cell region MCR to the connection region CON, and a portion of the gate electrode 160 disposed in the connection region CON may be referred to as an extension portion 120E.

A length of the extension portion 160E of each of the plurality of gate electrodes 160 in the horizontal direction may increase progressively toward the fourth surface CS_2 of the cell structure CS.

A plurality of extension portions 160E may have a stair shape, and an end of each of the plurality of extension portions 160E may be connected to the pad part 160P. The pad part 160P may have a thickness which is greater than the extension portion 160E in the vertical direction Z.

In some implementations, the gate electrode 160 may include a buried conductive layer and a conductive barrier layer surrounding an upper surface, a bottom surface, and a side surface of the buried conductive layer. For example, the buried conductive layer may include metal such as tungsten, nickel, cobalt, or tantalum, metal silicide, such as tungsten silicide, nickel silicide, cobalt silicide, or tantalum silicide, doped polysilicon, or a combination thereof. In some implementations, the conductive barrier layer may include titanium nitride, tantalum nitride, tungsten nitride, or a combination thereof.

In FIGS. 2, 6A, and 6B, the gate electrode 160 may correspond to a ground selection line GSL, word lines WL1, WL2, . . . , WLn−1, and WLn (WL), and at least one string selection line SSL, which configure a memory cell string MS. For example, an uppermost gate electrode 160 may function as the ground selection line GSL, two lowermost gate electrodes 160 may function as the string selection line SSL, and the other gate electrodes 160 may function as the word line WL. Accordingly, the memory cell string MS where a ground selection transistor GST and a string selection transistor SST are serially connected to memory cell transistors MC1, MC2, . . . , MCn−1, and MCn therebetween may be provided. In some implementations, at least one of the gate electrodes 160 may function as a dummy word line, but is not limited thereto.

In FIGS. 4 to 6B, a stack separation insulation layer WLI may be disposed in a stack separation opening portion WLH which passes through the plurality of gate electrodes 160 and the plurality of mold insulation layers 162 and extends in the vertical direction Z. In some implementations, the stack separation insulation layer WLI may include an upper surface disposed at a vertical level which is higher than the uppermost gate electrode 160 and may protrude upward with respect to the uppermost gate electrode 160.

In FIG. 5, the gate electrode 160 disposed between a pair of stack separation opening portions WLH may configure one memory block BLK. Also, in one memory block BLK, at least one gate electrode 160 may be divided into two gate electrodes 160 by a string separation opening portion SSLH. A string separation insulation layer SSLI may be disposed in the string separation opening portion SSLH.

A stack insulation layer 164 may be disposed to surround the gate electrode 160, the extension portion 160E, and the pad part 160P, in the connection region CON and the pad region PRC. In a plain viewpoint, the stack insulation layer 164 may be disposed to surround the gate electrode 160.

The channel structure 170 may be disposed in a channel hole 130H which passes through the gate electrode 160 and the mold insulation layer 162 and extends in the vertical direction Z. The channel structure 170 may include a gate insulation layer 172, a channel layer 174, a buried insulation layer 176, and a channel pad 178.

The channel structure 170 may include a first end portion 170x disposed close to the second peripheral circuit structure PS2 and a second end portion 170y opposite to the first end portion 170x. In some implementations, the channel structure 170 may include a sidewall which is inclined so that a width of the first end portion 170x is greater than that of the second end portion 170y.

The channel layer 174 may have a cylinder shape. The gate insulation layer 172 may be disposed on an outer sidewall of the channel layer 174, and the buried insulation layer 176 may be disposed on an inner sidewall of the channel layer 174.

A bit line BL may be electrically connected to the first end portion 170x of the channel structure 170 through a bit line contact BLC, and the common source layer 180 may be connected to the second end portion 170y of the channel structure 170. The bit line BL may be configured to be electrically connected to the cell wiring structure 140.

In some implementations, the gate insulation layer 172 may have a structure including a tunneling dielectric layer, a charge storage layer, and a blocking dielectric layer, which are sequentially disposed on the outer sidewall of the channel layer 174. A relative thickness of each of the tunneling dielectric layer, the charge storage layer, and the blocking dielectric layer each configuring the gate insulation layer 172 may be variously modified.

The tunneling dielectric layer may include silicon oxide, hafnium oxide, aluminum oxide, zirconium oxide, and tantalum oxide. The charge storage layer may be a region capable of storing electrons passing through the tunneling dielectric layer from the channel layer 174 and may include silicon nitride, boron nitride, silicon boron nitride, or impurity-doped polysilicon. The blocking dielectric layer may include silicon oxide, silicon nitride, or metal oxide having a dielectric constant which is greater than that of silicon oxide. The metal oxide may include hafnium oxide, aluminum oxide, zirconium oxide, tantalum oxide, or a combination thereof.

The common source layer 180 may be disposed on an uppermost mold insulation layer 162. The common source layer 180 may be conformally formed to be connected to the second end portion 170y of the channel structure 170. In some implementations, the common source layer 180 may cover an upper surface of the stack separation insulation layer WLI.

In a plain viewpoint, the common source layer 180 may be disposed in an entire region of the cell region MCR. The common source layer 180 may not be provided in the connection region CON and the pad region PRC.

A vertical level of an upper surface of a portion of the common source layer 180 may differ from a vertical level of an upper surface of the other portion of the common source layer 180 contacting the second end portion 170y of the channel structure 170.

In some implementations, the common source layer 180 may conformally cover an upper surface of the channel layer 174 and an upper surface of the gate insulation layer 172. For example, the gate insulation layer 172 may be disposed at a level which is lower than the upper surface of the channel layer 174, and a portion of a sidewall and the upper surface of the channel layer 174 may be covered by common source layer 180, thereby securing a sufficient contact area between the channel layer 174 and the common source layer 180.

In some implementations, the common source layer 180 may include polysilicon, and a laser annealing process may be performed on the common source layer 180, and thus, the common source layer 180 may have a relatively large grain size and/or may have relatively good crystal quality.

In the connection region CON, the first contact plug CP1 may be disposed to pass through the extension portion 160E and the pad part 160P. The first contact plug CP1 may be configured to be electrically connected to one pad part 160P. A horizontal insulation pattern 166 may be disposed at a position vertically overlapping the pad part 160P electrically connected o the first contact plug CP1.

The horizontal insulation pattern 166 may be provided in plurality. The horizontal insulation pattern 166 may be disposed between the first contact plug CP1 and the extension portion 160E. Based on the horizontal insulation pattern 166, the first contact plug CP1 may be configured to be electrically connected to only one of the plurality of gate electrodes 160.

In some implementations, a third end portion CP1x of the first contact plug CP1 may be disposed at a position adjacent to the second peripheral circuit structure PS2, and a fourth end portion CP1y of the first contact plug CP1 may be disposed opposite to the third end portion CP1x. The first contact plug CP1 may include a sidewall which is inclined so that a width of the third end portion CP1x is greater than that of the fourth end portion CP1y.

The fourth end portion CP1y of the first contact plug CP1 may pass through the uppermost mold insulation layer 162 and may extend in the vertical direction Z, and an upper surface of the fourth end portion CP1y of the first contact plug CP1 may be covered by the first upper insulation layer 191.

In some implementations, the first contact plug CP1 may include a conductive buried layer and a barrier layer which surrounds an upper surface and a sidewall of the conductive buried layer and has a thin thickness. For example, the conductive buried layer may include metal, such as tungsten, nickel, cobalt, or tantalum, metal silicide such as tungsten silicide, nickel silicide, cobalt silicide, or tantalum silicide, doped polysilicon, or a combination thereof. The barrier layer may include titanium nitride, tantalum nitride, tungsten nitride, or a combination thereof.

In the pad region PRC, the second contact plug CP2 may be disposed to pass through the stack insulation layer 164. In some implementations, a fifth end portion CP2x of the second contact plug CP2 may be disposed at a position adjacent to the second peripheral circuit structure PS2, and a sixth end portion CP2y of the second contact plug CP2 may be disposed opposite to the fifth end portion CP2x.

The second contact plug CP2 may include a sidewall which is inclined so that a width of the fifth end portion CP2x is greater than that of the sixth end portion CP2y. The sixth end portion CP2y of the second contact plug CP2 may pass through the uppermost mold insulation layer 162 and may extend, and an upper surface of the sixth end portion CP2y of the second contact plug CP2 may be covered by the first upper insulation layer 191.

The bit line BL, the first contact plug CP1, and the second contact plug CP2 may be electrically connected to the first peripheral circuit structure PS1 and/or the second peripheral circuit structure PS2 through the cell bonding pad CBP and the first bonding pad BP1.

At least one of a plurality of second contact plugs CP2 may be electrically connected to the first peripheral circuit structure PS1 through the second through silicon via TSV2.

The second upper insulation layer 192 may be disposed on the first upper insulation layer 191. The second upper insulation layer 192 may cover the first upper insulation layer 191. In some implementations, the second upper insulation layer 192 may be omitted.

The backside via 194 passing through the second upper insulation layer 192 may be disposed. The backside via 194 may be provided in plurality. The backside via 194 may further extend in the vertical direction Z and may be inserted into the first upper insulation layer 191. The backside via 194 may be connected to the second contact plug CP2.

The backside pad 196 may be disposed on the second upper insulation layer 192. The backside pad 196 may be provided in plurality. The backside pad 196 may be connected to the backside via 194. The passivation layer 198 may be disposed on the second upper insulation layer 192, and a backside opening portion OUT of the passivation layer 198 may be exposed at an upper surface of the backside pad 196.

The backside pad 196 may be configured to be connected to an external device. The backside pad 196 may be configured to receive an external signal from the external device and transfer the external signal to the first peripheral circuit structure PS1 and/or the second peripheral circuit structure PS2.

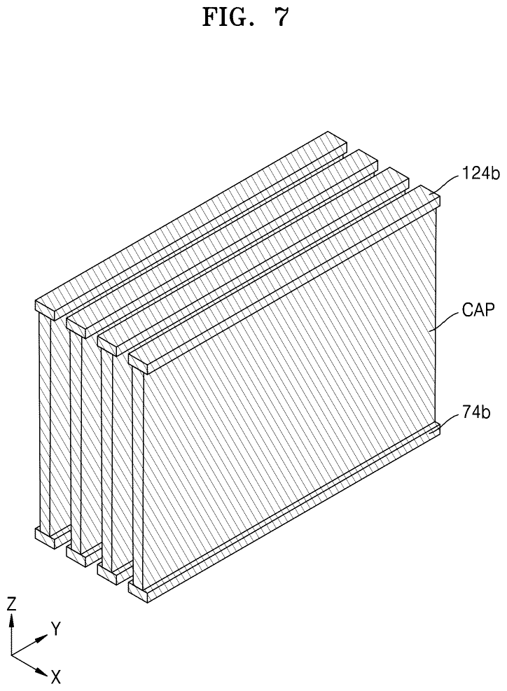

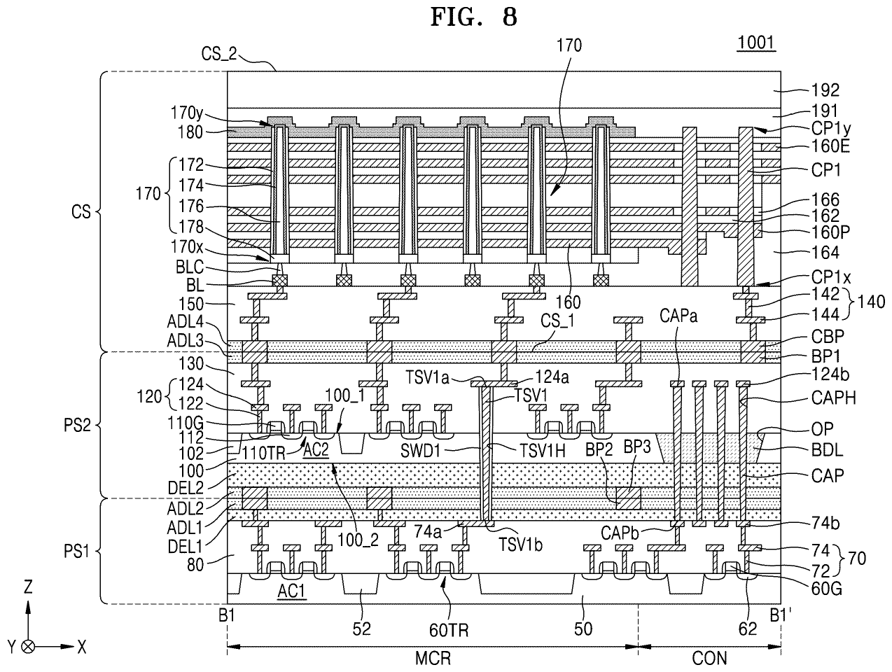

FIG. 7 is a perspective view for describing an example of a vertical structure CAP illustrated in FIG. 6A according to some implementations. In FIGS. 6A and 7, for example, a vertical structure CAP may extend long in a second horizontal direction Y. A length of the vertical structure CAP in the second horizontal direction Y may be greater than that of the vertical structure CAP in a first horizontal direction X. However, the first horizontal direction X or the second horizontal direction Y may be an example of a horizontal direction, and the horizontal direction in which the vertical structure CAP extends long may be diversified.

A first peripheral circuit wiring 74b and a second peripheral circuit wiring 124b, which are electrically connected to the vertical structure CAP, may extend long in the second horizontal direction Y along the vertical structure CAP.

The vertical structure CAP, and the first peripheral circuit wiring 74b and the second peripheral circuit wiring 124b, which are electrically connected to the vertical structure CAP, may configure an electrode plate of a capacitor.

The vertical structure CAP, and the first peripheral circuit wiring 74b and the second peripheral circuit wiring 124b, which are electrically connected to the vertical structure CAP, may extend long in one horizontal direction, and thus, an area of the electrode plate of the capacitor may increase. In this case, a capacitance of the capacitor may increase.

In some implementations, a shape of the vertical structure CAP may be diversified. For example, one vertical structure CAP may have a cylindrical shape, and the other one vertical structure CAP adjacent thereto may have a hollow cylindrical shape. The other one vertical structure CAP may be expressed as having a macaroni shape. In this case, an area of an electrode plate of a capacitor configured with one vertical structure CAP and the other one vertical structure CAP may increase. As described above, a shape of the vertical structure CAP may be variously modified so that a capacitance of a capacitor configured with two or more vertical structures CAP and dielectric elements increases.

FIG. 8 is a cross-sectional view taken along line B1-B1′ of FIG. 5 according to some implementations. Hereinafter, except for descriptions which are the same as or similar to the descriptions of FIGS. 4 to 6A, only a difference will be described.

In FIG. 8, a semiconductor device 1001 may further include a second bonding pad BP2 and a third bonding pad BP3. The second bonding pad BP2 may be an element included in a first peripheral circuit structure PS1. The third bonding pad BP3 may be an element included in a second peripheral circuit structure PS2. Each of the second bonding pad BP2 and the third bonding pad BP3 may be provided in plurality.

The second bonding pad BP2 may be disposed between a first dielectric layer DEL1 and a second adhesive layer ADL2. A first adhesive layer ADL1 may surround at least a portion of a side surface of the second bonding pad BP2.

The third bonding pad BP3 may be disposed between a second dielectric layer DEL2 and the first adhesive layer ADL1. The second adhesive layer ADL2 may surround at least a portion of a side surface of the third bonding pad BP3.

The second bonding pad BP2 may contact the third bonding pad BP3, and the second bonding pad BP2 and the third bonding pad BP3 may be configured as one body. However, in some implementations, and the second bonding pad BP2 and the third bonding pad BP3 may be configured to be differentiated from each other.

The second bonding pad BP2 may contact the third bonding pad BP3, the first adhesive layer ADL1 may contact the second adhesive layer ADL2, and the first peripheral circuit structure PS1 may be hybrid-bonded to the second peripheral circuit structure PS2.

At least one of a plurality of second bonding pads BP2 may be electrically connected to a first peripheral circuit wiring structure 70. The third bonding pad BP3 may be electrically connected to the second bonding pad BP2. At least one of a plurality of third bonding pads BP3 may be electrically connected to a second peripheral circuit wiring structure 120.

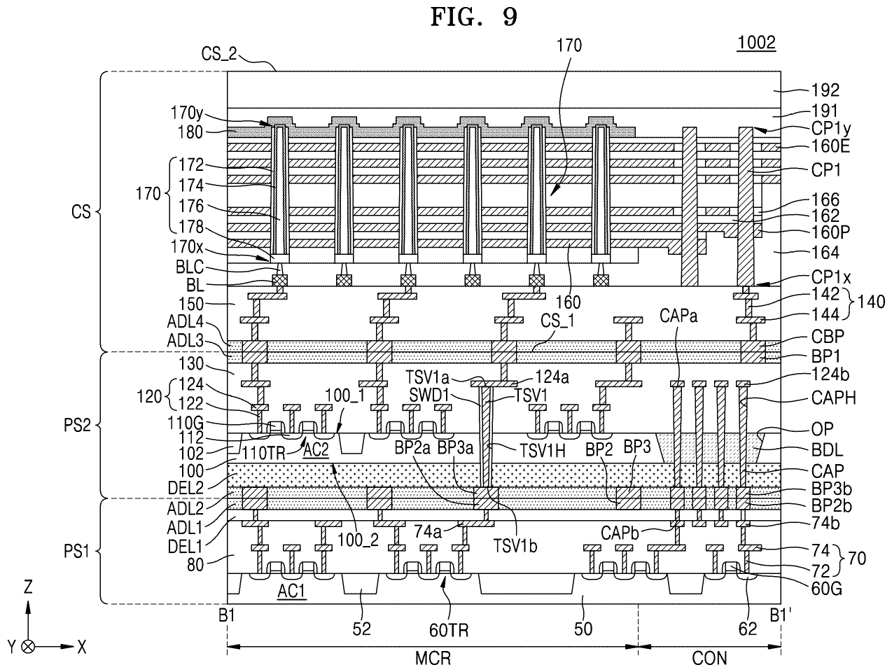

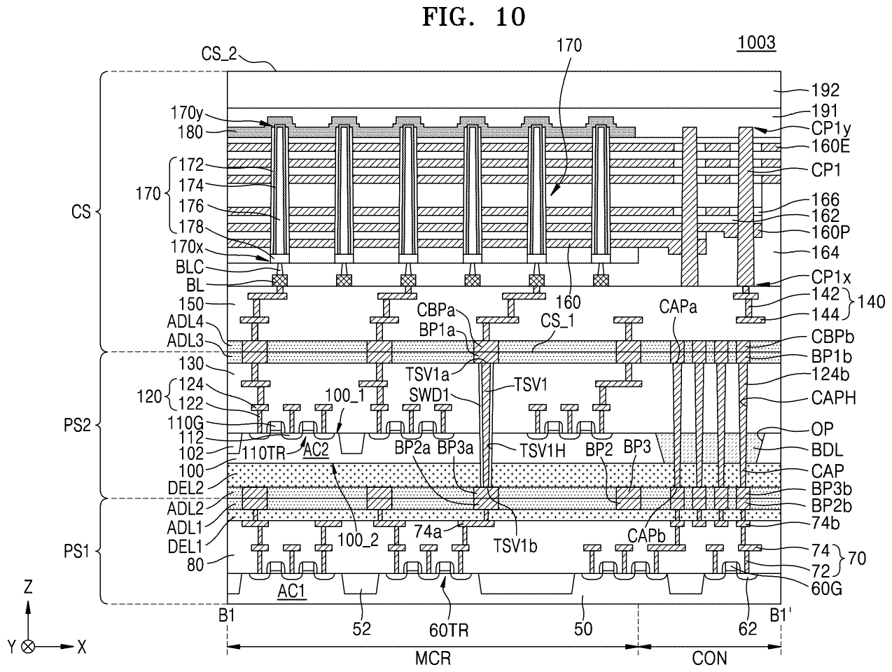

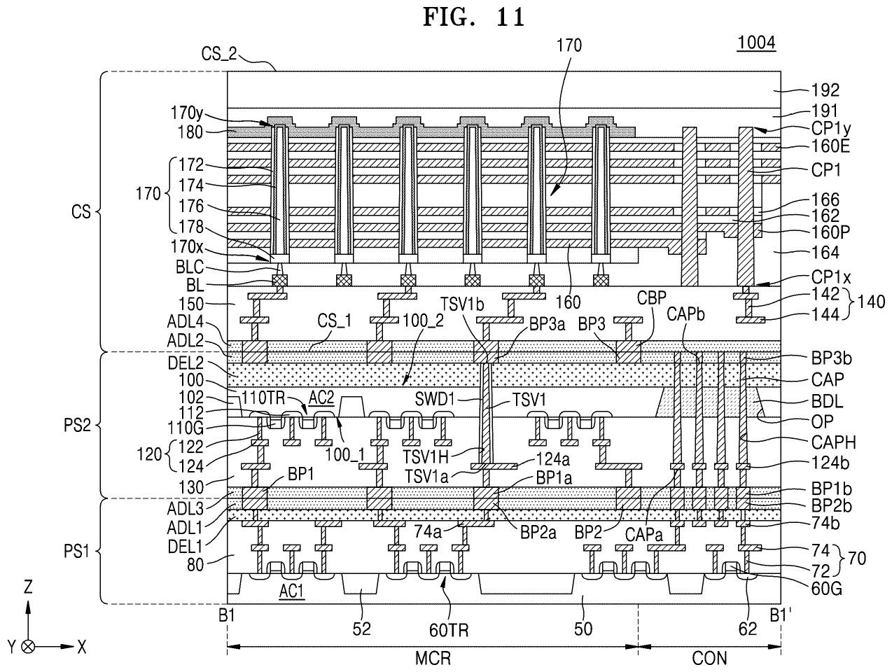

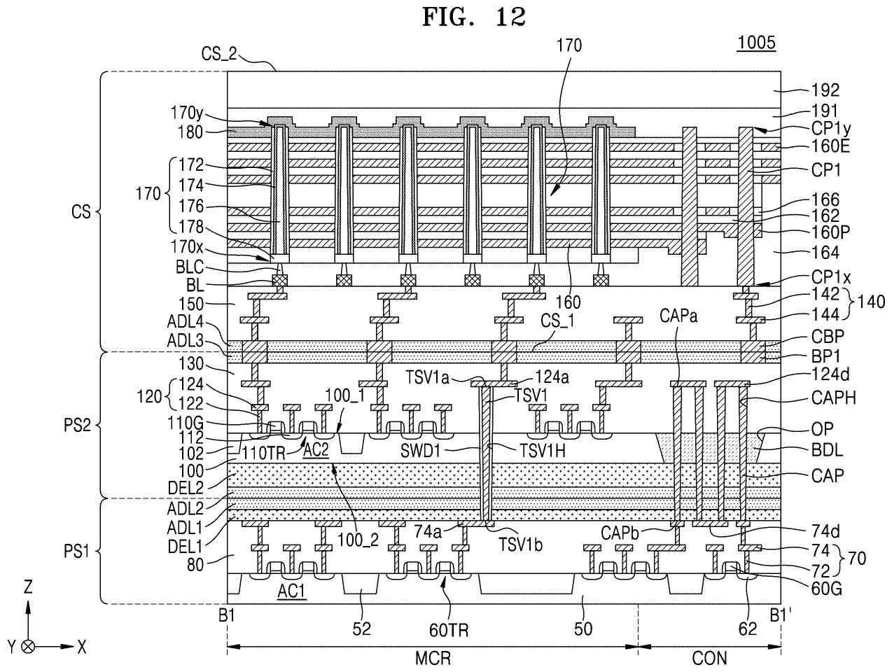

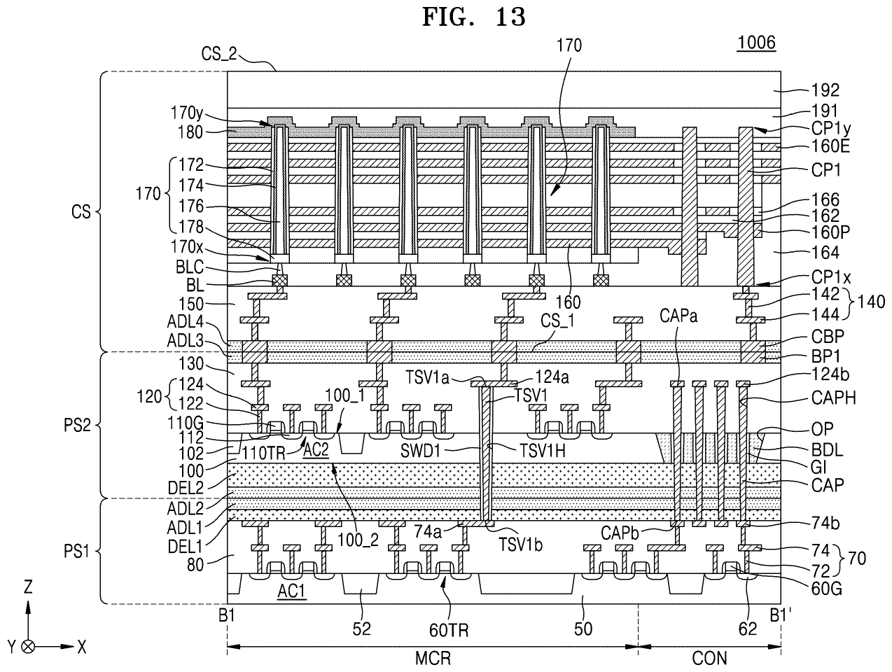

FIG. 9 is a cross-sectional view taken along line B1-B1′ of FIG. 5 according to some implementations. Hereinafter, except for descriptions which are the same as or similar to the descriptions of FIG. 8, only a difference will be described.

In FIG. 9, a first through silicon via TSV1 of a semiconductor device 1002 may be connected to one third bonding pad BP3a of a plurality of third bonding pads BP3. The third bonding pad BP3a connected to the first through silicon via TSV1 may be connected to one second bonding pad BP2a of a plurality of second bonding pads BP2.

The first through silicon via TSV1 may pass through a second substrate 100 and a second dielectric layer DEL2 and may not pass through a second adhesive layer ADL2, a first adhesive layer ADL1, and a first dielectric layer DEL1. A vertical level of a lower surface TSV1b of the first through silicon via TSV1 may be substantially the same as a vertical level of an upper surface of the second adhesive layer ADL2.

The first through silicon via TSV1 may be electrically connected to a first peripheral circuit wiring structure 70.

A vertical structure CAP may be connected to one third bonding pad BP3b of the plurality of third bonding pads BP3. The third bonding pad BP3b connected to the vertical structure CAP may be connected to one second bonding pad BP2b of the plurality of second bonding pads BP2.

The vertical structure CAP may pass through a buried pattern BDL and the second dielectric layer DEL2 and may not pass through the second adhesive layer ADL2, the first adhesive layer ADL1, and the first dielectric layer DEL1. A vertical level of a lower surface CAPb of the vertical structure CAP may be substantially the same as a vertical level of the upper surface of the second adhesive layer ADL2.

At least one of a plurality of vertical structures CAP may be electrically connected to a first peripheral circuit wiring structure 70 through the third bonding pad BP3b and the second bonding pad BP2b.

In some implementations, similar to the first through silicon via TSV1, the second through silicon via TSV2 may be connected to one of the plurality of third bonding pads BP3. The description of FIG. 9 on the other second through silicon via TSV2 may be similar to the description of FIG. 9 on the first through silicon via TSV1, and a description thereof is omitted.

A horizontal-direction (for example, a first horizontal direction X) width of the third bonding pad BP3b connected to the vertical structure CAP may be less than a horizontal-direction (for example, the first horizontal direction X) width of the third bonding pad BP3a connected to the first through silicon via TSV1. Accordingly, a distance between two or more vertical structures CAP configuring an electrode plate of a capacitor may decrease. Accordingly, a capacitance of the capacitor may increase, and thus, an electrical characteristic of the semiconductor device 1002 may be enhanced.

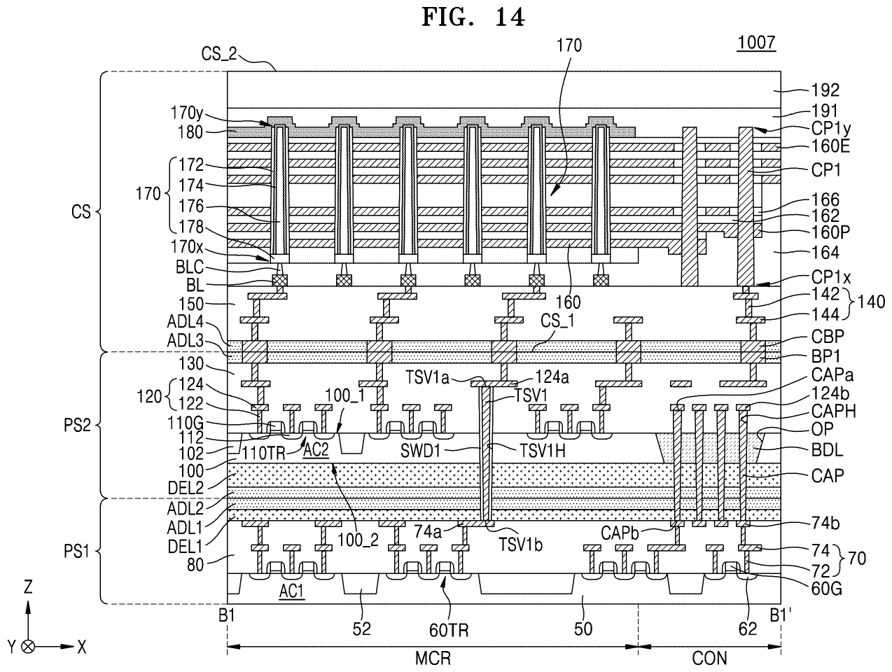

FIG. 10 is a cross-sectional view taken along line B1-B1′ of FIG. 5 according to some implementations. Hereinafter, except for descriptions which are the same as or similar to the descriptions of FIG. 9, only a difference will be described.

In FIG. 10, a first through silicon via TSV1 of a semiconductor device 1003 may be directly connected to one first bonding pad BP1a of a plurality of first bonding pads BP1. The first bonding pad BP1a connected to the first through silicon via TSV1 may be connected to one cell bonding pad CBPa of a plurality of cell bonding pads CBP.

At this time, the first through silicon via TSV1 may not be electrically connected to a second peripheral circuit wiring structure 120. At least one of a plurality of channel structures 170 may be electrically connected to a first peripheral circuit wiring structure 70 through the cell bonding pad CBPa, the first bonding pad BP1a, a third bonding pad BP3a, and a second bonding pad BP2a.

The vertical structure CAP may further extend in a vertical direction Z and may be directly connected to one first bonding pad BP1b of a plurality of first bonding pads BP1. The first bonding pad BP1b connected to the vertical structure CAP may be connected to one cell bonding pad CBPb of the plurality of cell bonding pads CBP.

At this time, the vertical structure CAP may not be electrically connected to the second peripheral circuit wiring structure 120. At least one of the plurality of channel structures 170 may be electrically connected to the first peripheral circuit wiring structure 70 through the cell bonding pad CBPb, the first bonding pad BP1b, a third bonding pad BP3b, and a second bonding pad BP2b.

A horizontal-direction (for example, a first horizontal direction X) width of the first bonding pad BP1b connected to the vertical structure CAP may be less than a horizontal-direction (for example, the first horizontal direction X) width of the first bonding pad BP1a connected to the first through silicon via TSV1. A horizontal-direction (for example, the first horizontal direction X) width of the first bonding pad BP1b connected to the vertical structure CAP may be less than a horizontal-direction (for example, the first horizontal direction X) width of the other first bonding pad BP1 which is not connected to the vertical structure CAP. Therefore, a distance between two or more vertical structures CAP configuring an electrode plate of a capacitor may decrease. Accordingly, a capacitance of the capacitor may increase, and electrical characteristics of the semiconductor device 1003 may be enhanced.

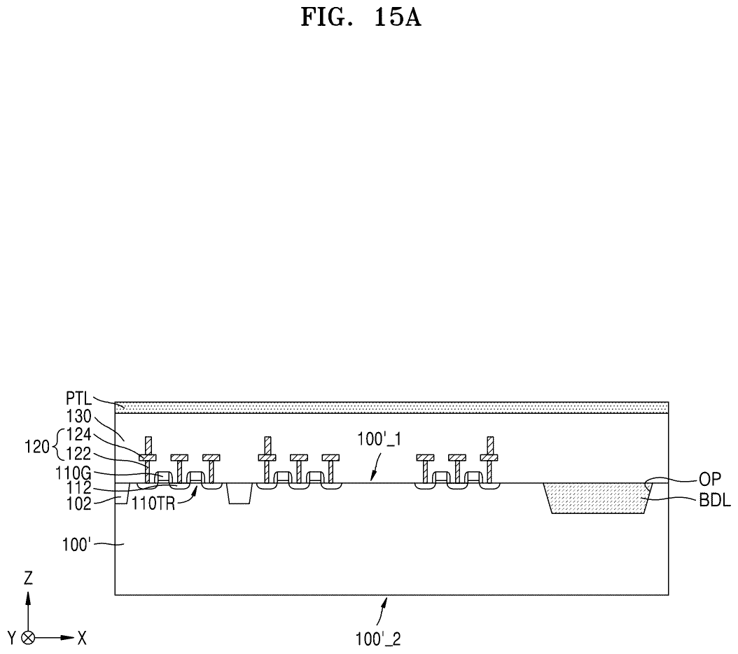

FIG. 11 is a cross-sectional view taken along line B1-B1′ of FIG. 5 according to some implementations. Hereinafter, except for descriptions which are the same as or similar to the descriptions of FIG. 9, only a difference will be described.

In FIG. 11, a second peripheral circuit structure PS2 of a semiconductor device 1004 may have a structure where the second peripheral circuit structure PS2 of the semiconductor device 1002 of FIG. 9 is vertically reversed.

A first surface 100_1 of a second substrate 100 of the second peripheral circuit structure PS2 may be disposed to face the first peripheral circuit structure PS1, and a second surface 100_2 of the second substrate 100 may be disposed to face a cell structure CS.

The lower surface TSV1b of the first through via TSV1 of FIG. 9 may face upward (i.e., in a vertical direction Z) in FIG. 11. Likewise, the upper surface TSV1a of the first through via TSV1 of FIG. 9 may face downward (i.e., in a direction opposite to the vertical direction Z) in FIG. 11.

A third bonding pad BP3a connected to the first through silicon via TSV1 may be connected to one of a plurality of cell bonding pads CBP. The first bonding pad BP1a connected to the first through silicon via TSV1 may be connected to one second bonding pad BP2a of a plurality of second bonding pads BP2.

The lower surface CAPb of the vertical structure CAP of FIG. 9 may face upward (i.e., in the vertical direction Z) in FIG. 11. Likewise, the upper surface CAPa of the vertical structure CAP of FIG. 9 may face downward (i.e., in the direction opposite to the vertical direction Z) in FIG. 11.

A third bonding pad BP3b connected to the vertical structure CAP may not be connected to the cell bonding pad CBP. In some implementations, the third bonding pad BP3b connected to the vertical structure CAP may be connected to the cell bonding pad CBP. In this case, the cell bonding pad CBP connected to the third bonding pad BP3b connected to the vertical structure CAP may not be connected to a cell wiring structure 140.

FIG. 12 is a cross-sectional view taken along line B1-B1′ of FIG. 5 according to some implementations. Hereinafter, except for descriptions which are the same as or similar to the descriptions of FIG. 6A, only a difference will be described.

In FIG. 12, a plurality of vertical structures CAP of a semiconductor device 1005 may be electrically connected to each other. Two or more vertical structures CAP may be electrically connected to each other by one second peripheral circuit wiring 124d. In some implementations, two or more vertical structures CAP may be electrically connected to each other by one first peripheral circuit wiring 74d.

The vertical structure CAP may include, for example, impurity-doped polysilicon. In this case, a resistance of the vertical structure CAP may vary based on a concentration of doped impurities. For example, a resistance of the vertical structure CAP may be adjusted by adjusting a concentration of doped impurities.

In this case, the vertical structure CAP, the first peripheral circuit wiring 74d, and the second peripheral circuit wiring 124d may function as a resistor. To increase a resistance of the vertical structure CAP, a concentration of impurities doped on the vertical structure CAP may decrease. On the other hand, in order to decrease a resistance of the vertical structure CAP, a concentration of impurities doped on the vertical structure CAP may increase.

According to some implementations, the vertical structure CAP of the semiconductor device 1005 may include impurity-doped polysilicon. Also, the vertical structure CAP may extend in a vertical direction Z, a vertical length of the vertical structure CAP may be easily adjusted. In this case, a resistance of the vertical structure CAP may be affected by a vertical length of the vertical structure CAP. Accordingly, a vertical length of the vertical structure CAP may be easily adjusted, and a resistance of the vertical structure CAP may be easily adjusted. Also, a vertical length of the vertical structure CAP may be easily adjusted, and thus, a one-dimensional area of the vertical structure CAP may decrease. Accordingly, the degree of integration of the semiconductor device 1005 may be enhanced instead of that a resistor is formed on an upper surface of a first substrate 50 or a first surface 100_1 of a second substrate 100.

FIG. 13 is a cross-sectional view taken along line B1-B1′ of FIG. 5 according to some implementations. Hereinafter, except for descriptions which are the same as or similar to the descriptions of FIG. 6A, only a difference will be described.

In FIG. 13, a buried pattern BDL of a semiconductor device 1006 may include a conductive material. For example, the buried pattern BDL may include a metal material, such as tungsten, aluminum, copper, gold, silver, cobalt, or molybdenum, but is not limited thereto.

The semiconductor device 1006 may further include a gate insulation layer GI disposed between the buried pattern BDL and the vertical structure CAP. The buried pattern BDL and the vertical structure CAP may be apart from each other in a horizontal direction with the gate insulation layer GI therebetween. The buried pattern BDL and the vertical structure CAP may be configured to be electrically disconnected from each other with the gate insulation layer GI therebetween. The gate insulation layer GI may include a low-k dielectric material such as silicon oxide, or may include a high-k dielectric material such as hafnium oxide.

The buried pattern BDL may be electrically connected to a second peripheral circuit transistor 110TR through a second peripheral circuit wiring structure 120, or may be electrically connected to a first peripheral circuit wiring structure 70 through the other elements.

The vertical structure CAP may include, for example, single crystalline silicon, polysilicon, or amorphous silicon. The vertical structure CAP may include impurity-doped silicon.

The vertical structure CAP, the buried pattern BDL, and the gate insulation layer GI may configure a vertical transistor. A portion of the vertical structure CAP overlapping the buried pattern BDL in a horizontal direction may function a channel, and the other portion of the vertical structure CAP may function as a source or a drain. The buried pattern BDL may function as a gate of a transistor.

The semiconductor device 1006 may include the vertical structure CAP, the buried pattern BDL, and the gate insulation layer GI. The vertical structure CAP may pass through the buried pattern BDL in the vertical direction Z, and the gate insulation layer GI may be disposed between the buried pattern BDL and the vertical structure CAP. Accordingly, the vertical structure CAP, the buried pattern BDL, and the gate insulation layer GI may function as a gate of a transistor. Accordingly, the number of first peripheral circuit transistors 60TR formed on an upper surface of a first substrate 50 and the number of second peripheral circuit transistors 110TR formed on a first surface 100_1 of a second substrate 100 may decrease. For this reason, the degree of integration of the semiconductor device 1006 may be enhanced.

FIG. 14 is a cross-sectional view taken along line B1-B1′ of FIG. 5 according to some implementations. Hereinafter, except for descriptions which are the same as or similar to the descriptions of FIGS. 4 to 6A, only a difference will be described.

Referring to FIG. 14, a vertical level of an upper surface CAPa of a vertical structure CAP of a semiconductor device 1007 may differ from a vertical level of an upper surface TSV1a of a first through silicon via TSV1. For example, the vertical level of the upper surface CAPa of the vertical structure CAP may be lower than the vertical level of the upper surface TSV1a of the first through silicon via TSV1. In some implementations, unlike the illustration of FIG. 14, the vertical level of the upper surface CAPa of the vertical structure CAP may be higher than the vertical level of the upper surface TSV1a of the first through silicon via TSV1. This may be modified based on a design of the semiconductor device 1007 to implement.

A horizontal thickness of the vertical structure CAP of the semiconductor device 1007 may differ from a horizontal thickness of the first through silicon via TSV1. A horizontal thickness may denote a thickness, measured at an arbitrary vertical level, of the vertical structure CAP in a first horizontal direction X or a second horizontal direction Y. For example, a horizontal thickness of the vertical structure CAP may be less than the horizontal thickness of the first through silicon via TSV1. In some implementations, unlike the illustration of FIG. 14, the horizontal thickness of the vertical structure CAP may be greater than the horizontal thickness of the first through silicon via TSV1. This may be modified based on a design of the semiconductor device 1007 to implement.

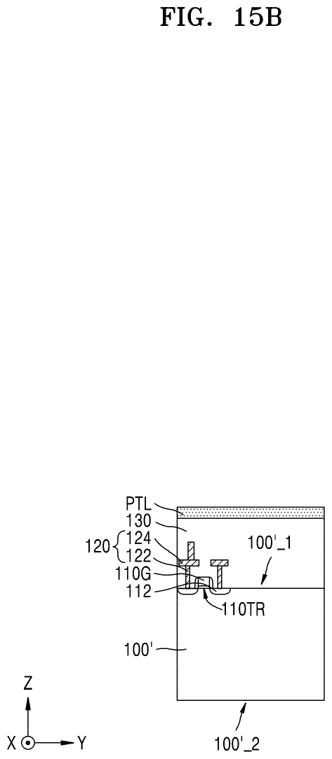

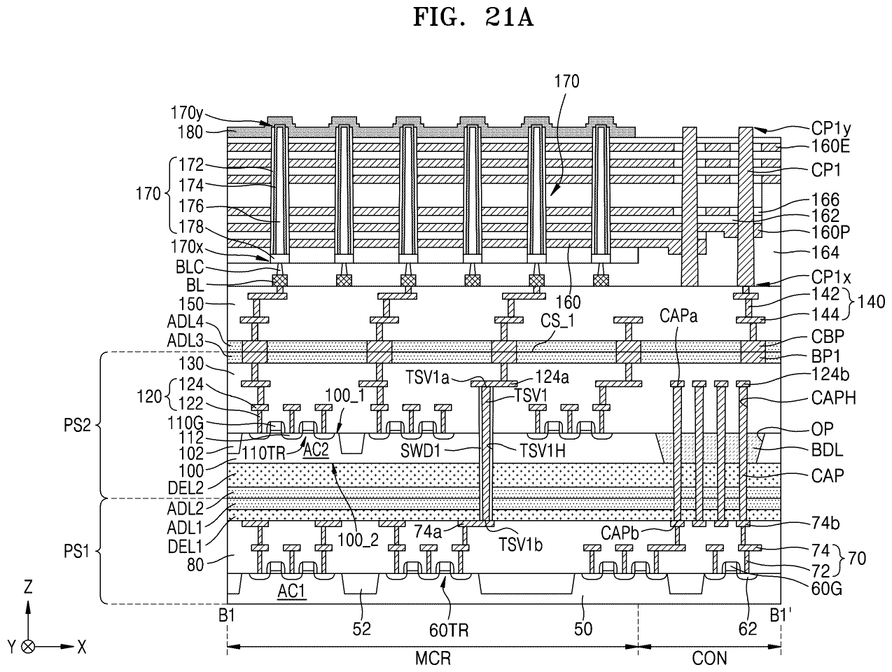

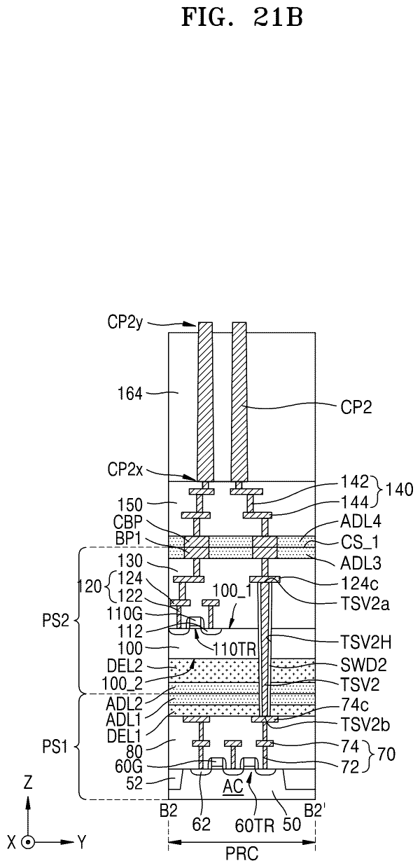

FIGS. 15A to 21B are diagrams illustrating an example of a method of manufacturing a semiconductor device according to some implementations, in which, FIGS. 15A, 16A, 17A, 18A, 19A, 20A, and 21A are cross-sectional views taken along line B1-B1′ of FIG. 5, and FIGS. 15B, 16B, 17B, 18B, 19B, 20B, and 21B are cross-sectional views taken along line B2-B2′ of FIG. 5.

Referring to FIGS. 15A and 15B, a second substrate 100′ may be provided. The second substrate 100′ may include a material that may be included in the second substrate 100 described above with reference to FIGS. 6A and 6B. The second substrate 100′ may include a first surface 100′_1 and a second surface 100′_2 opposite to the first surface 100′_1.

A second device isolation layer 102 may be formed on the first surface 100′_1 of the second substrate 100′. Subsequently, a buried pattern BDL may be formed on the first surface 100′_1 of the second substrate 100′. A process of forming the buried pattern BDL may include a process of forming a mask pattern, a process of performing an etching process on the first surface 100′_1 of the second substrate 100′ by using a mask pattern as an etch mask to form an opening portion OP, a process of forming a buried layer filling the opening portion OP, and a process of performing a planarization process on the buried layer.

In FIGS. 15A and 15B, the opening portion OP may not pass through the second substrate 100. In FIGS. 15A and 15B, the opening portion OP may be referred to as a trench or a recess. However, the phrase “opening portion OP” may be used in FIGS. 15A and 15B, for matching the descriptions of FIGS. 6A and 6B.

A second peripheral circuit gate 110G and a second peripheral circuit transistor 110TR including a second source/drain region 112 disposed at both sides of the second peripheral circuit gate 110G may be formed on the first surface 100′_1 of the second substrate 100′.

A second peripheral circuit wiring structure 120 electrically connected to the second peripheral circuit transistor 110TR may be formed. The second peripheral circuit wiring structure 120 may include a second peripheral circuit contact 122 and a second peripheral circuit wiring 124.

A second peripheral circuit insulation layer 130 covering the second peripheral circuit wiring structure 120 may be formed. Subsequently, a protection layer PTL may be formed on the second peripheral circuit insulation layer 130. The protection layer PTL may include, for example, an insulating material such as SiCN.

Referring to FIGS. 15A and 15B, a first carrier substrate 300 may be prepared. The first carrier substrate 300 may include silicon, germanium, silicon germanium (SiGe), gallium arsenic (GaAs), indium gallium arsenic (InGaAs), aluminum gallium arsenic (AlGaAs), or a compound thereof.

As the second substrate 100′ described with reference to FIGS. 15A and 15B is vertically reversed, the protection layer PTL may face the first carrier substrate 300, and the second substrate 100′ and a structure including elements formed on the second substrate 100′ may be attached to the first carrier substrate 300. Accordingly, the first surface 100′_1 of the second substrate 100′ may face the first carrier substrate 300. The second surface 100′_2 of the second substrate 100′ may face in an upward direction (i.e., a vertical direction Z).

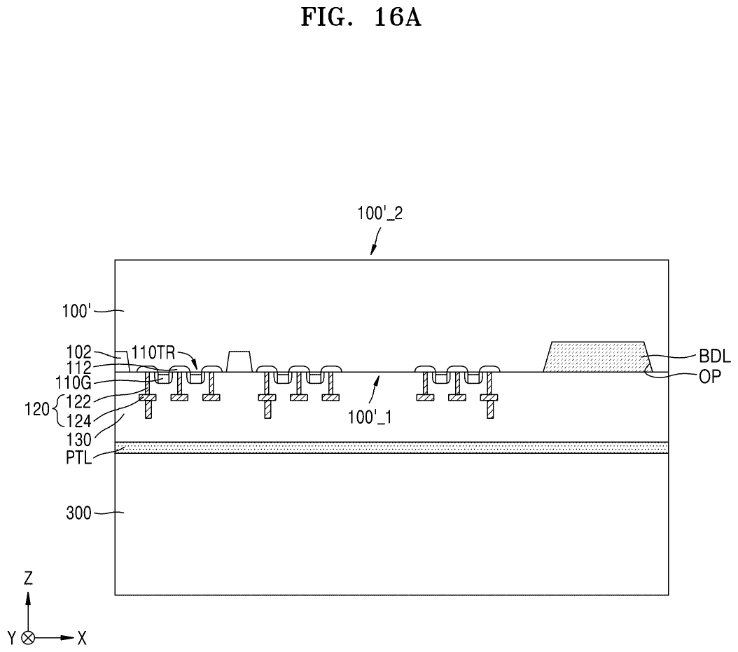

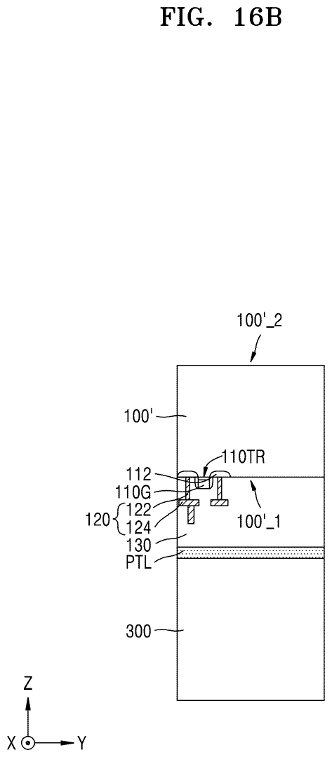

Referring to FIGS. 16A and 16B, a planarization process may be performed on the second surface 100′_2 of the second substrate 100′ of FIGS. 15A and 15B. The planarization process may stop after the buried pattern BDL is exposed. Based on the planarization process, the buried pattern BDL may have a shape which passes through the second substrate 100′.

A second dielectric layer DEL2 and a second adhesive layer ADL2 may be sequentially formed on the second surface 100′_2 of the second substrate 100′.

A first peripheral circuit structure PS1 may be prepared. The first peripheral circuit structure PS1 may include a first substrate 50, a first device isolation layer 52, a first peripheral circuit transistor 60TR, a first peripheral circuit wiring structure 70, a first peripheral circuit insulation layer 80, a first dielectric layer DEL1, and a first adhesive layer ADL1.

As the first carrier substrate 300 is vertically reversed, the second surface 100′_2 of the second substrate 100′ may face the first peripheral circuit structure PS1, and the first adhesive layer ADL1 may be bonded to the second adhesive layer ADL2.

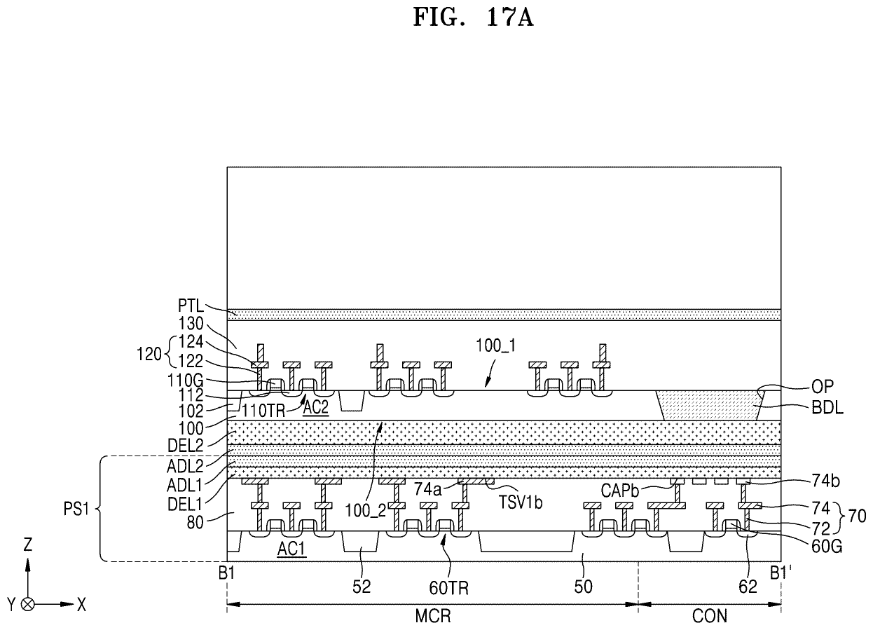

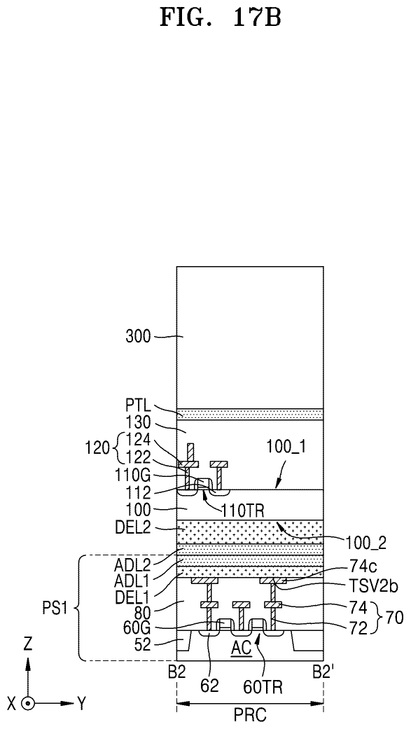

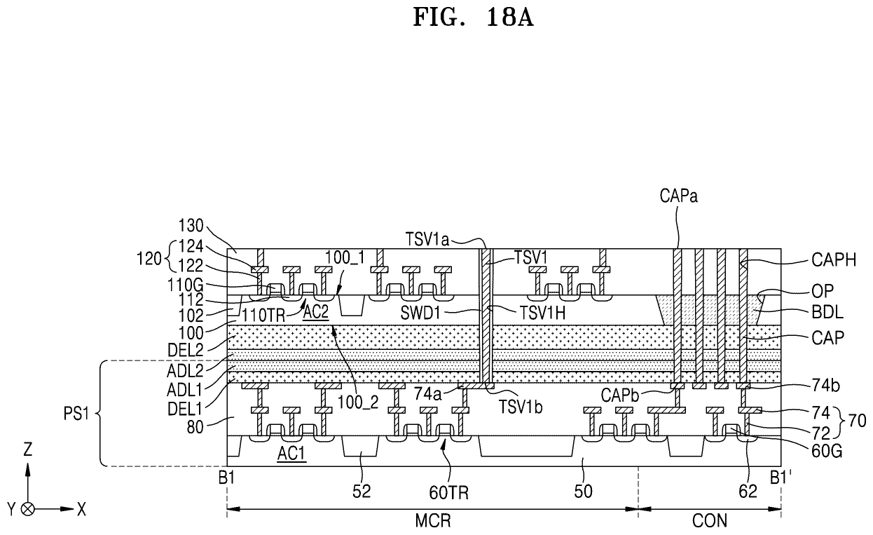

Referring to FIGS. 17A and 17B, a grinding process and/or an etching process may be performed on the first carrier substrate 300 and the protection layer PTL. Based on the grinding process and/or the etching process, the first carrier substrate 300 and the protection layer PTL may be removed. Based on the grinding process and/or the etching process, a portion of a second peripheral circuit insulation layer 130 may be removed.

A first through silicon via TSV1, a second through silicon via TSV2, and a vertical structure CAP may be formed. For example, a mask pattern may be formed, and an etching process may be performed by using the mask pattern as an etch mask. A first through silicon via hole TSV1H, a second through silicon via hole TSV2H, and a vertical structure hole CAPH may be formed by the etching process. The first through silicon via hole TSV1H and the second through silicon via hole TSV2H may pass through the second peripheral circuit insulation layer 130, a second substrate 100, a second dielectric layer DEL2, a second adhesive layer ADL2, the first adhesive layer ADL1, and the first dielectric layer DEL1. The vertical structure hole CAPH may pass through the second peripheral circuit insulation layer 130, a buried pattern BDL, the second dielectric layer DEL2, the second adhesive layer ADL2, the first adhesive layer ADL1, and the first dielectric layer DEL1.

Subsequently, a conductive material layer filling the first through silicon via hole TSV1H, the second through silicon via hole TSV2H, and the vertical structure hole CAPH may be formed, and a planarization process may be performed on the conductive material layer. After the planarization process is performed, the first through silicon via TSV1, the second through silicon via TSV2, and the vertical structure CAP may be formed from the conductive material layer.

Before forming the first through silicon via TSV1 and the second through silicon via TSV2, a first sidewall insulation pattern SWD1 may be formed in the first through silicon via hole TSV1H, and a second sidewall insulation pattern SWD2 may be formed in the second through silicon via hole TSV2H.

The first through silicon via hole TSV1H and the second through silicon via hole TSV2H may be formed, a sidewall insulation layer conformally covering sidewalls of the first through silicon via hole TSV1H and the second through silicon via hole TSV2H may be formed, and by performing an etch-back process or a planarization process on the sidewall insulation layer, the first sidewall insulation pattern SWD1 and the second sidewall insulation pattern SWD2 may be formed. In this case, the vertical structure hole CAPH may be formed simultaneously with the first through silicon via hole TSVIH and the second through silicon via hole TSV2H. In some implementations, the vertical structure hole CAPH, the first through silicon via hole TSV1H, and the second through silicon via hole TSV2H may be sequentially formed.

Because the vertical structure hole CAPH is formed simultaneously with the first through silicon via hole TSV1H and the second through silicon via hole TSV2H, a vertical level of a lower surface CAPb of the vertical structure CAP may be substantially the same as a vertical level of a lower surface TSV1b of the first through silicon via TSV1 and a vertical level of a lower surface TSV2b of the second through silicon via TSV2.

Even in a case where the vertical structure hole CAPH, the first through silicon via hole TSV1H, and the second through silicon via hole TSV2H are sequentially formed, the other elements may not be formed until before all of the vertical structure hole CAPH, the first through silicon via hole TSV1H, and the second through silicon via hole TSV2H are formed. Therefore, even in this case, the vertical level of a lower surface CAPb of the vertical structure CAP may be substantially the same as the vertical level of the lower surface TSV1b of the first through silicon via TSV1 and the vertical level of the lower surface TSV2b of the second through silicon via TSV2.

In a case where the vertical structure hole CAPH, the first through silicon via hole TSV1H, and the second through silicon via hole TSV2H are simultaneously or sequentially formed, a time for manufacturing a semiconductor device (1000 of FIG. 6A) may be reduced.

The first through silicon via TSV1, the second through silicon via TSV2, and the vertical structure CAP may be electrically connected to a corresponding element of the first peripheral circuit wiring structure 70.

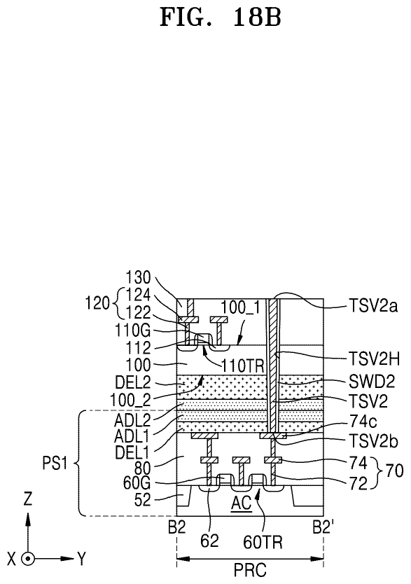

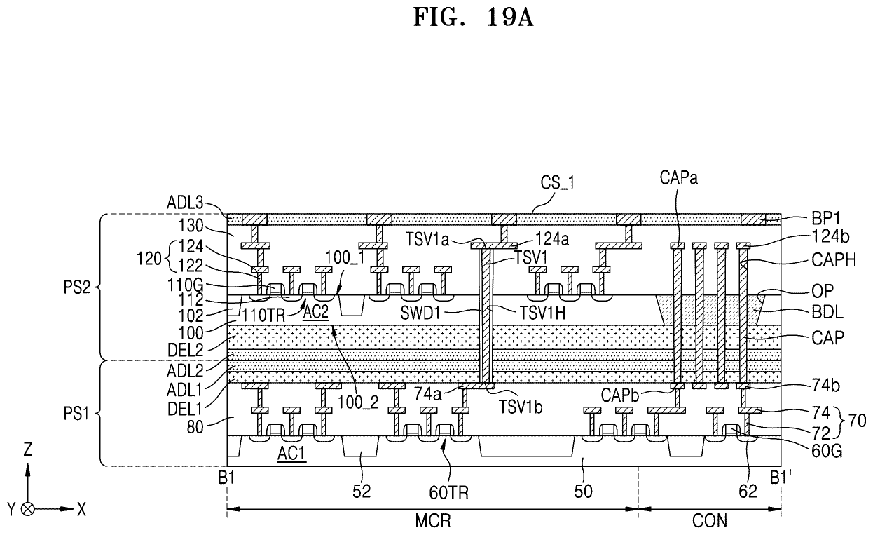

In FIGS. 18A and 18B, the other element of the second peripheral circuit wiring structure 120 may be further formed. In such a process, a vertical thickness of the second peripheral circuit insulation layer 130 may further increase, but is not limited thereto.

A third adhesive layer ADL3 and a first bonding pad BP1 may be formed on the second peripheral circuit insulation layer 130. The third adhesive layer ADL3 may surround at least a portion of a side surface of the first bonding pad BP1 but may not cover an upper surface of the first bonding pad BP1.

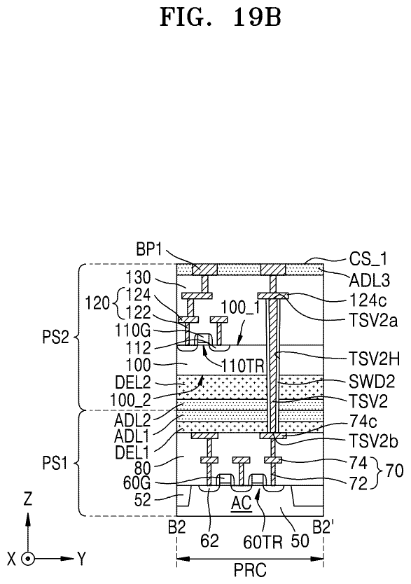

Referring to FIGS. 19A and 19B, a second carrier substrate 310 may be provided. In embodiments, the second carrier substrate 310 may include silicon, germanium, SiGe, GaAs, InGaAs, AlGaAs, or a compound thereof.

A plurality of gate electrodes 160 and a plurality of mold insulation layers 162 may be formed to be alternately stacked on the second carrier substrate 310, and an extension portion 160E and a pad part 160P each connected to a gate electrode 160 may be formed in a connection region (CON of FIG. 6). Also, a channel structure 170 which passes through the gate electrode 160 and extends in the vertical direction Z and a bit line BL connected to the channel structure 170 may be formed in a cell region (MCR of FIG. 6A). Also, a stack insulation layer 164 surrounding the gate electrode 160, the extension portion 160E, and the pad part 160P may be formed in the connection region (CON of FIG. 6A) and the pad region (PRC of FIG. 6B). Also, a first contact plug CP1 passing through the extension portion 160E and the pad part 160P may be formed in the connection region (CON of FIG. 6A), and a second contact plug CP2 passing through the stack insulation layer 164 may be formed in the pad region (PRC of FIG. 6B).

The channel structure 170, the first contact plug CP1, and the second contact plug CP2 may further extend in the vertical direction Z and may be inserted into the second carrier substrate 310. Also, a cell wiring insulation layer 150 and a cell wiring structure 140 may be formed on the bit line BL, the first contact plug CP1, and the second contact plug CP2. The cell wiring structure 140 may be electrically connected to the bit line BL, the first contact plug CP1, and the second contact plug CP2. A fourth adhesive layer ADL4 and a cell bonding pad CBP may be formed on the cell wiring insulation layer 150.

In FIGS. 19A and 19B, in conjunction with FIG. 5, a stack separation opening portion WLH that passes through the gate electrode 160 and the mold insulation layer 162 and extends in the vertical direction Z may be formed, and a stack separation insulation layer WLI may be formed in the stack separation opening portion WLH. The stack separation insulation layer WLI may further extend in the vertical direction Z and may be inserted into the second carrier substrate 310.

In some implementations, in a process of forming the channel structure 170, a first end portion 170x of the channel structure 170 may be disposed at a vertical level which is higher than a second end portion 170y of the channel structure 170, and the second end portion 170y may be formed to extend to the inside of the second carrier substrate 310.

In some implementations, in a process of forming the first contact plug CP1, a third end portion CP1x of the first contact plug CP1 may be formed to have a width which is greater than that of a fourth end portion CP1y of the first contact plug CP1, and the fourth end portion CP1y of the first contact plug CP1 may be formed to extend to the inside of the second carrier substrate 310.

In some implementations, in a process of forming the second contact plug CP2, a fifth end portion CP2x of the second contact plug CP2 may be formed to have a width which is greater than that of a sixth end portion CP2y of the second contact plug CP2, and the sixth end portion CP2y of the second contact plug CP2 may be formed to extend to the inside of the second carrier substrate 310.

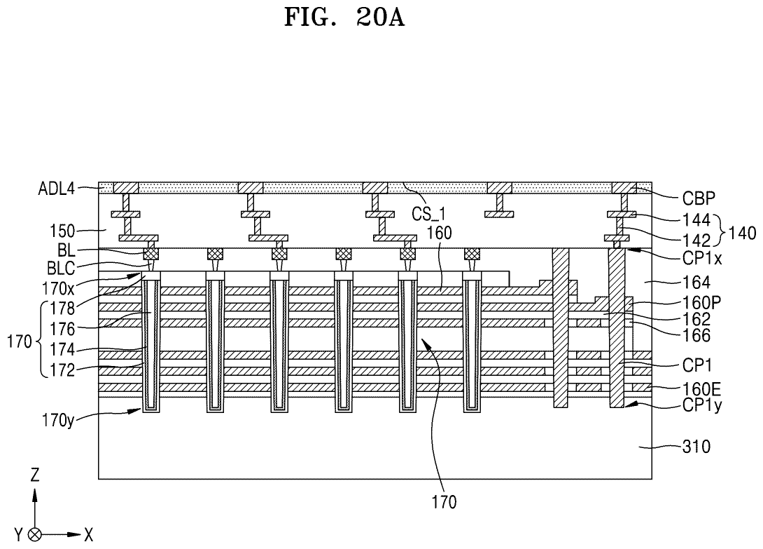

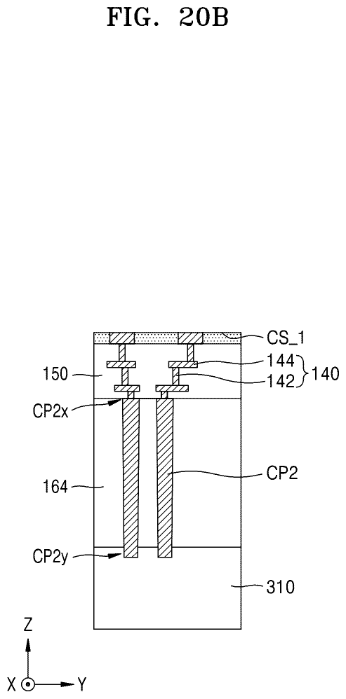

Referring to FIGS. 20A and 20B, as the second carrier substrate 130 is vertically reversed, the fourth adhesive layer ADLA may face the third adhesive layer ADL3, and the fourth adhesive layer ADL4 may be attached to the third adhesive layer ADL3. At this time, the cell bonding pad CBP may contact the first bonding pad BP1.

Subsequently, the second carrier substrate 310 may be removed by a grinding process or/and an etching process. As the second carrier substrate 310 is removed, the second end portion 170y of the channel structure 170 may be exposed. Likewise, as the second carrier substrate 310 is removed, the fourth end portion CP1y of the first contact plug CP1 and the sixth end portion CP2y of the second contact plug CP2 may be exposed. Although not shown, as the second carrier substrate 310 is removed, an upper portion of the stack separation insulation layer WLI may be exposed.

An upper surface of the channel layer 174 may be exposed by removing a portion of the gate insulation layer 172 exposed at the second end portion 170y of the channel structure 170. In some implementations, an upper surface of the gate insulation layer 172 may be disposed at a level which is lower than an upper surface of the channel layer 174, and an upper side of the gate insulation layer 172 may be further removed so that a portion of a sidewall and an upper surface of the channel layer 174 are exposed.

Subsequently, a tilt ion implantation process may be performed on the channel layer 174. The tilt ion implantation process may denote an ion implantation process which is performed at an inclined angle with respect to the vertical direction Z. In the tilt ion implantation process, impurities of a first conductive type may be implanted into the channel layer 174. The first conductive type may include, for example, a P type, but is not limited thereto.

Subsequently, a common source layer 180 may be formed. A process of forming the common source layer 180 may include a process of conformally forming a preliminary common source layer on an uppermost mold insulation layer 162 of mold insulation layers 162 and exposed upper surfaces of the channel layer 174, a process of performing an ion implantation process on a preliminary source layer by using a photo mask layer, and a process of removing the preliminary common source layer disposed in the connection region CON and the pad region PRC. The common source layer may be formed of polysilicon.

Subsequently, a laser annealing process may be performed on the common source layer 180. In some implementations, the laser annealing process may be performed to enhance the degree of crystallization of the common source layer 180 disposed in the cell region MCR, or increase a grain size of the common source layer 180, or decrease a resistance of the common source layer 180. In some implementations, the laser annealing process may be performed on the preliminary common source layer before performing the ion implantation process.

Referring again to FIGS. 6A and 6B, the first upper insulation layer 191 covering the common source layer 180 may be formed. The first upper insulation layer 191 may cover the uppermost mold insulation layer 162 of the mold insulation layers 162 and a fourth end portion CP1y of the first contact plug CP1, in the connection region CON. The first upper insulation layer 191 may cover the stack insulation layer 164 and a sixth end portion CP2y of the second contact plug CP2, in the pad region PRC.

The second upper insulation layer 192 may be formed on the first upper insulation layer 191. A process of the second upper insulation layer 192 may be omitted. The second upper insulation layer 192 may cover the first upper insulation layer 191. Subsequently, backside vias 194 passing through the second upper insulation layer 192 may be formed. Each of the backside vias 194 may be disposed to be connected to the second contact plug CP2.

The backside pad 196 connected to the backside vias 194 may be formed on the second upper insulation layer 192. Subsequently, the passivation layer 198 covering the backside pad 196 may be formed on the second upper insulation layer 192, and the backside opening portion OUT may be formed in the passivation layer 168 to expose an upper surface of the backside pad 196. Accordingly, the semiconductor device 1000 may be manufactured.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. Embodiments have been described by using the terms described herein, but this has been merely used for describing the inventive concept and has not been used for limiting a meaning or limiting the scope of the inventive concept defined in the following claims. Accordingly, the spirit and scope of the inventive concept may be defined based on the spirit and scope of the following claims.

What is claimed is:

1. A semiconductor device comprising:
a first substrate;
a plurality of gate electrodes stacked on an upper surface of the first substrate in a vertical direction, the plurality of gate electrodes being spaced apart from one another in the vertical direction;
a channel structure extending through the plurality of gate electrodes;
a second substrate disposed between the first substrate and a lowermost gate electrode of the plurality of gate electrodes, the second substrate including a first surface and a second surface opposite to the first surface;
a buried pattern extending through the second substrate; and
a vertical structure extending through the buried pattern,
wherein the buried pattern comprises a dielectric material.

2. The semiconductor device of claim 1, further comprising:
a first peripheral circuit transistor disposed on the upper surface of the first substrate; and
a second peripheral circuit transistor disposed on the first surface of the second substrate,
wherein the vertical structure is configured to be electrically connected to at least one of the first peripheral circuit transistor and the second peripheral circuit transistor.

3. The semiconductor device of claim 1, wherein the buried pattern comprises a material having a dielectric constant greater than a dielectric constant of silicon oxide.

4. The semiconductor device of claim 1, further comprising a first adhesive layer and a second adhesive layer each disposed between the first substrate and the second substrate,
wherein the second adhesive layer is disposed between the first adhesive layer and the second substrate, and
wherein the first adhesive layer contacts the second adhesive layer.

5. The semiconductor device of claim 4, wherein the vertical structure further extends through the first adhesive layer and the second adhesive layer.

6. The semiconductor device of claim 4, further comprising:
a first dielectric layer disposed between the first adhesive layer and the first substrate; and
a second dielectric layer disposed between the second adhesive layer and the second substrate,
wherein the vertical structure extends through the first dielectric layer, the first adhesive layer, the second adhesive layer, and the second dielectric layer.

7. The semiconductor device of claim 6, wherein the first dielectric layer and the second dielectric layer comprise a material having a dielectric constant greater than a dielectric constant of silicon oxide.

8. The semiconductor device of claim 1, further comprising:
a first bonding pad disposed between the first substrate and the second substrate;
a first adhesive layer surrounding at least a portion of a side surface of the first bonding pad;
a second bonding pad disposed between the second substrate and the first adhesive layer; and
a second adhesive layer surrounding at least a portion of a side surface of the second bonding pad,
wherein the first bonding pad contacts the second bonding pad,
wherein the first adhesive layer contacts the second adhesive layer, and
wherein the vertical structure is connected to the second bonding pad.

9. The semiconductor device of claim 8,
wherein the first bonding pad is one of a plurality of first bonding pads and the second bonding pad is one of a plurality of second bonding pads, and
wherein a horizontal-direction width of the second bonding pad of the plurality of second bonding pads that is connected to the vertical structure is less than a horizontal-direction width of another second bonding pad of the plurality of second bonding pads that is not connected to the vertical structure.

10. The semiconductor device of claim 1, wherein a length of the vertical structure in a first horizontal direction is greater than a length of the vertical structure in a second horizontal direction intersecting with the first horizontal direction.

11. The semiconductor device of claim 1, further comprising:
a first peripheral circuit transistor disposed on the upper surface of the first substrate; and
a second peripheral circuit transistor disposed on the first surface of the second substrate,
wherein the first surface of the second substrate faces the first substrate.

12. A semiconductor device comprising:
a first substrate;
a first peripheral circuit transistor disposed on an upper surface of the first substrate;
a plurality of gate electrodes stacked on the upper surface of the first substrate in a vertical direction, the plurality of gate electrodes being spaced apart from one another in the vertical direction;
a channel structure extending through the plurality of gate electrodes;
a second substrate disposed between the first substrate and a lowermost gate electrode of the plurality of gate electrodes, the second substrate including a first surface and a second surface opposite to the first surface;
a second peripheral circuit transistor disposed on the first surface of the second substrate;
a first through silicon via extending through the second substrate, the first through silicon via being electrically connected to the first peripheral circuit transistor and the channel structure;
a buried pattern extending through the second substrate; and
a vertical structure extending through the buried pattern,
wherein a vertical level of a lower surface of the first through silicon via is substantially the same as a vertical level of a lower surface of the vertical structure.

13. The semiconductor device of claim 12, further comprising:
a stack insulation layer surrounding at least a portion of a side surface of each of the plurality of gate electrodes;
a contact plug extending through the stack insulation layer; and
a second through silicon via extending through the second substrate, the second through silicon via being electrically connected to the contact plug,
wherein a vertical level of a lower surface of the second through silicon via is substantially the same as a vertical level of a lower surface of the vertical structure.

14. The semiconductor device of claim 12, wherein the vertical structure comprises impurity-doped polysilicon.

15. The semiconductor device of claim 14, further comprising:
a first peripheral circuit wiring structure disposed between the first substrate and the second substrate and electrically connected to the first peripheral circuit transistor; and
a second peripheral circuit wiring structure disposed between the second substrate and a lowermost gate electrode of the plurality of gate electrodes and electrically connected to the second peripheral circuit transistor,
wherein the vertical structure is one of a plurality of vertical structures, and
wherein two or more of the plurality of vertical structures are connected to each other by the first peripheral circuit wiring structure or the second peripheral circuit wiring structure.

16. The semiconductor device of claim 14, further comprising a gate insulation layer disposed between the buried pattern and the vertical structure,
wherein the buried pattern comprises a conductive material.

17. The semiconductor device of claim 12, wherein a vertical level of an upper surface of the first through silicon via is substantially the same as a vertical level of an upper surface of the vertical structure.

18. The semiconductor device of claim 12, wherein the buried pattern comprises a material having a dielectric constant greater than a dielectric constant of silicon oxide.

19. A semiconductor device comprising:
a first peripheral circuit structure;
a cell structure on the first peripheral circuit structure; and
a second peripheral circuit structure disposed between the first peripheral circuit structure and the cell structure,
wherein the first peripheral circuit structure comprises:
a first substrate including a cell region, a connection region next to the cell region, and a pad region surrounding at least a portion of each of the cell region and the connection region;
a first peripheral circuit transistor disposed on an upper surface of the first substrate; and
a first peripheral circuit wiring structure electrically connected to the first peripheral circuit transistor, wherein the second peripheral circuit structure comprises:
a second substrate including a first surface and a second surface opposite to the first surface;
a second peripheral circuit transistor disposed on the first surface of the second substrate;
a second peripheral circuit wiring structure electrically connected to the second peripheral circuit transistor on the first surface of the second substrate;
a buried pattern extending through the second substrate; and
a vertical structure extending through the buried pattern and electrically connected to the first peripheral circuit wiring structure, and wherein the cell structure comprises:
a plurality of gate electrodes spaced apart from one another in a vertical direction, in the cell region;
a channel structure extending through the plurality of gate electrodes and extending in the vertical direction in the cell region;
a pad part extending from each of the plurality of gate electrodes and disposed in the connection region;
a first contact plug extending through the pad part, in the vertical direction, and connected to the pad part;
a stack insulation layer surrounding at least a portion of a side surface of each of the plurality of gate electrodes; and
a second contact plug extending through the stack insulation layer in the pad region.

20. The semiconductor device of claim 19,
wherein the second peripheral circuit structure further comprises a through silicon via extending through the second substrate and electrically connected to the first peripheral circuit wiring structure and the second peripheral circuit wiring structure, and
wherein a vertical level of a lower surface of the through silicon via is substantially the same as a vertical level of a lower surface of the vertical structure.
